(19) United States
(12) Patent Application Publication
(10) Pub. No.: US 2024/0274564 A1
(43) Pub. Date: Aug. 15, 2024

(54) MICRO BUMP, INTERPOSER FOR ELECTRICAL CONNECTION HAVING SAME, SEMICONDUCTOR PACKAGE, MULTI-LAYER STACKED SEMICONDUCTOR DEVICE, AND DISPLAY

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 18/567,363

(22) PCT Filed: Jun. 3, 2022
(86) PCT No.: PCT/KR2022/007926

§ 371 Date: Dec. 6, 2023

(30) Foreign Application Priority Data
Jun. 7, 2021 (KR) 10-2021-0073235

(51) Int. Cl. H01L 23/00

(52) U.S. Cl. CPC H01L 24/13; H01L 24/11; H01L 2224/1111; H01L 2224/11462; H01L 2224/13012; H01L 2224/13014; H01L 2224/13018; H01L 2224/13082; H01L 2224/13109; H01L 2224/13111; H01L 2224/13113; H01L 2224/13116; H01L 2224/13124; H01L 2224/13139; H01L 2224/13144; H01L 2224/13147; H01L 2224/1318; H01L 2224/13181; H01L 2224/13184

(57) ABSTRACT

The present invention relates to a micro bump, which is capable of coping with a narrow pitch between terminals and preventing an increase in current density and thermal energy density at a bump connection portion, and to an interposer for electrical connection having same, a semiconductor package, a multi-layer stacked semiconductor device, and a display. The micro bump may be manufactured using: an electrically conductive material part forming step of forming an electrically conductive material part inside a through hole provided in a body made of an anodized film; and a bonding material part forming step of forming a bonding material part on at least a portion of an upper portion and a lower portion of the electrically conductive material part.

### TECHNICAL FIELD

The present disclosure relates to a micro bump, an interposer for electrical connection having the same, a semiconductor package, a multi-layer stacked semiconductor device, and a display.

### BACKGROUND ART

A conventional flip-chip bonding method using solder bumps has been generally used because it is advantageous over a wire bonding method in that the electrical performance is excellent due to a minimized connection length between a chip and a substrate, the degree of integration of input/output terminals is high, and the internal heat can be rapidly dissipated by distributing the heat dissipation path.

With the recent trend of semiconductor chips toward the integration of multiple functions in one chip and faster processing speed, the number of input/output terminals has been increased and the pitch between the terminals has been increasingly reduced.

As the pitch between the terminals has become narrower, the pitch between solder bumps has also naturally become narrower. However, in the case of the conventional method using the solder bumps, there is a high possibility that when a solder bump is melted, a short-circuit occurs between adjacent solder bumps. To solve this, it may be considered to reduce the size of the solder bump. However, when the size of the solder bump is reduced, the distance between the chip and the substrate becomes too short, thereby increasing the difficulty of an underfill process, and the current density and thermal energy density in a bump connection part increase due to the reduced size of the solder bump.

### DOCUMENTS OF RELATED ART

### Patent Documents

(Patent Document 1) Korean Patent No. 10-1610326

### DISCLOSURE

### Technical Problem

Accordingly, the present disclosure has been made keeping in mind the above problems occurring in the related art, and an objective of the present disclosure is to provide a micro bump, an interposer for electrical connection having the same, a semiconductor package, a multi-layer stacked semiconductor device, and a display that can cope with a narrow pitch between terminals and prevent an increase in current density and thermal energy density in a bump connection part.

### Technical Solution

In order to accomplish the above objective, according to one aspect of the present disclosure, there is provided a method of manufacturing a micro bump, the method including: an electrically conductive material part forming step of forming an electrically conductive material part in a plurality of through-holes provided in a body made of an anodic aluminum oxide film; and a bonding material part forming step of forming a bonding material part on at least a part of upper and lower portions of the electrically conductive material part.

Meanwhile, according to another aspect of the present disclosure, there is provided an interposer for electrical connection, the interposer including: a body made of an anodic aluminum oxide film having a plurality of through-holes; and a micro bump provided in each of the through-holes. Here, the micro bump may include: an electrically conductive material part; and a bonding material part provided on at least a part of upper and lower portions of the electrically conductive material part.

In addition, the electrically conductive material part may include at least one selected from among Cu, Al, W, Au, Ag, Mo, Ta, and an alloy thereof, and the bonding material part may include at least one selected from among Sn, AgSn, Au, PbSn, SnAgCu, SnAgBi, AuSn, In, InSn, and an alloy containing Sn.

In addition, the bonding material part may include: a first bonding material part provided on the lower portion of the electrically conductive material part; and a second bonding material part provided on the upper portion of the electrically conductive material part.

In addition, the first bonding material part may be formed to protrude from an upper surface of the body, and the second bonding material part may be formed to protrude from a lower surface of the body.

In addition, the first bonding material part may be formed not to protrude from an upper surface of the body, and the second bonding material part may be formed to protrude from a lower surface of the body.

In addition, the first bonding material part may be formed not to protrude from an upper surface of the body, and the second bonding material part may be formed not to protrude from a lower surface of the body.

Meanwhile, according to another aspect of the present disclosure, there is provided a micro bump, including: an electrically conductive material part; a bonding material part provided on at least a part of an upper portion and a lower portion of the electrically conductive material part; and a plurality of fine trenches provided in a side surface of the electrically conductive material part.

In addition, the fine trenches may be provided along the entire circumference of the side surface of the electrically conductive material part.

In addition, the bonding material part may include: a first bonding material part provided on the lower portion of the electrically conductive material part; and a second bonding material part provided on the upper portion of the electrically conductive material part.

In addition, the micro bump may further include: a seed layer provided between the first bonding material part and the electrically conductive material part.

In addition, the micro bump may further include: a functional layer between provided the electrically conductive material part and the bonding material part.

In addition, the fine trenches may also be provided on at least a part of a side surface of the bonding material part.

Meanwhile, according to another aspect of the present disclosure, there is provided a semiconductor package, including: a semiconductor device; a substrate on which the semiconductor device is mounted; and a plurality of micro bumps provided between the semiconductor device and the substrate. Here, the micro bumps may have a column shape, and a plurality of fine trenches may be provided on at least a part of a side surface of each of the micro bumps in a circumferential direction.

Meanwhile, according to another aspect of the present disclosure, there is provided a semiconductor package, including: a semiconductor device; a substrate on which the semiconductor device is mounted; and a plurality of micro bumps provided under the substrate. Here, the micro bumps may have a column shape, and a plurality of fine trenches may be provided on at least a part of a side surface of each of the micro bumps in a circumferential direction.

Meanwhile, according to another aspect of the present disclosure, there is provided a multi-layer stacked semiconductor device, including: a plurality of semiconductor devices; and a plurality of micro bumps provided between the semiconductor devices. Here, the micro bumps may have a column shape, and a plurality of fine trenches may be provided on at least a part of a side surface of each of the micro bumps in a circumferential direction.

Meanwhile, according to another aspect of the present disclosure, there is provided a display, including: a semiconductor device; a substrate on which the semiconductor device is mounted; and a plurality of micro bumps provided between the semiconductor device and the substrate. Here, the micro bumps may have a column shape, and a plurality of fine trenches may be provided on at least a part of a side surface of each of the micro bumps in a circumferential direction.

### Advantageous Effects

The present disclosure can provide a micro bump, an interposer for electrical connection having the same, a semiconductor package, a multi-layer stacked semiconductor device, and a display that can cope with a narrow pitch between terminals and prevent an increase in current density and thermal energy density in a bump connection part.

### DESCRIPTION OF DRAWINGS

FIG. 1 is a perspective view illustrating a micro bump according to a first embodiment of the present disclosure.

FIGS. 2A to 3C are views illustrating a method of manufacturing the micro bump according to the first embodiment of the present disclosure.

FIG. 4 is a perspective view illustrating a micro bump according to a second embodiment of the present disclosure.

FIGS. 5A to 6B are views illustrating a method of manufacturing the micro bump according to the second embodiment of the present disclosure.

FIG. 7 is a perspective view illustrating a micro bump according to a third embodiment of the present disclosure.

FIGS. 8A to 9C are views illustrating a method of manufacturing the micro bump according to the third embodiment of the present disclosure.

FIG. 10 is a perspective view illustrating a micro bump according to a fourth embodiment of the present disclosure.

FIGS. 11A to 12C are views illustrating a method of manufacturing the micro bump according to the fourth embodiment of the present disclosure.

FIG. 13A is a perspective view illustrating a micro bump according to a fifth embodiment of the present disclosure.

FIG. 13B is a perspective view illustrating a micro bump according to a sixth embodiment of the present disclosure.

FIG. 14A is a perspective view illustrating a micro bump according to a seventh embodiment of the present disclosure.

FIG. 14B is a perspective view illustrating a micro bump according to an eighth embodiment of the present disclosure.

FIGS. 15A to 15D are views illustrating an interposer for electrical connection according to an embodiment of the present disclosure.

FIGS. 16A and 16B are views illustrating a semiconductor package according to an embodiment of the present disclosure.

FIGS. 17 to 27 are views illustrating a method of manufacturing the semiconductor package according to the embodiment of the present disclosure.

FIG. 28 is a view illustrating a state in which the semiconductor package according to the embodiment of the present disclosure is mounted on a circuit board.

FIG. 29 is a view illustrating a multi-layer stacked semiconductor device according to an embodiment of the present disclosure.

FIGS. 30A to 33B are views illustrating a method of manufacturing a display according to an embodiment of the present disclosure.

FIG. 34 is an image illustrating an upper surface of a micro bump according to a first embodiment of the present disclosure.

FIG. 35 is an image illustrating a side surface of the micro bump according to the first embodiment of the present disclosure.

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, in principle, all the conditional terms and embodiments listed in this description are clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, thicknesses of films and regions in the figures may be exaggerated. Therefore, variations from the shapes of the illustrations as a result, for example, of manufacturing techniques and/or tolerances, are to be expected. In addition, a limited number of micro bumps are illustrated in the drawings by way of example. Thus, the embodiments should not be construed as limited to the particular shapes of regions illustrated herein but are to include deviations in shapes that result, for example, from manufacturing. The technical terms used herein are for the purpose of describing particular embodiments only and should not be construed as limiting the present disclosure. As used herein, the singular forms are intended to include the plural forms as well, unless the context clearly indicates otherwise. It will be further understood that the terms “comprise”, “include”, “have”, etc. when used herein, specify the presence of stated features, integers, steps, operations, elements, components, and/or combinations thereof but do not preclude the presence or addition of one or more other features, integers, steps, operations, elements, components, and/or combinations thereof.

Hereinafter, exemplary embodiments of the present disclosure will be described in detail with reference to the accompanying drawings. Wherever possible, the same reference numerals will be used throughout different embodiments and the description to refer to the same or like elements or parts. In addition, the configuration and operation already described in other embodiments will be omitted for convenience.

A semiconductor device 10 to be described below may be a memory chip, a microprocessor chip, a logic chip, a light-emitting device, which have fine-pitched chip terminals, or a combination thereof. The semiconductor device 10 is not particularly limited and examples thereof include a logic LSI (such as an ASIC, an FPGA, and an ASSP), a microprocessor (such as a CPU and a GPU), a memory (such as DRAM and a hybrid memory cube (HMC), a magnetic RAM (MRAM), a phase-change memory (PCM), resistive RAM (ReRAM), a ferroelectric RAM (FeRAM), a flash memory (such as NAND flash), a semiconductor light-emitting device (such as an LED, a mini LED, and a micro LED), a power device, an analog IC (such as a DC-AC converter and an insulating gate bipolar transistor (IGBT)), an MEMS (such as an acceleration sensor, a pressure sensor, a vibrator, and a gyro sensor), a wireless device (such as a GPS, an FM, an NFC, an RFEM, an MMIC, and a WLAN), a discrete device, a BSI, a CIS, a camera module, a CMOS, a passive device, a GAW filter, an RF filter, an RF IPD, an APE, and a BB.

In addition, a substrate 20 to be described below includes a circuit board, a wiring board, a package substrate, a temporary substrate, an intermediate substrate, and the like, and also includes all substrates electrically connected to the semiconductor device 10 directly or indirectly.

First, micro bumps 150 according to embodiments of the present disclosure will be described hereinafter.

### Micro Bump 150 According to First Embodiment

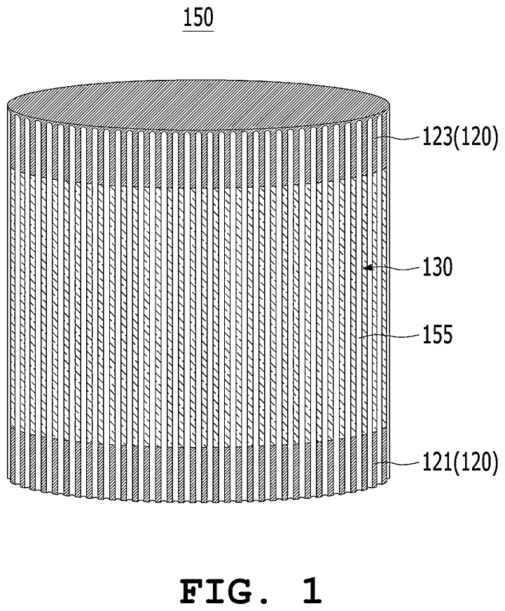

Hereinafter, a micro bump 150 according to a first embodiment of the present disclosure will be described with reference to FIGS. 1 to 3C.

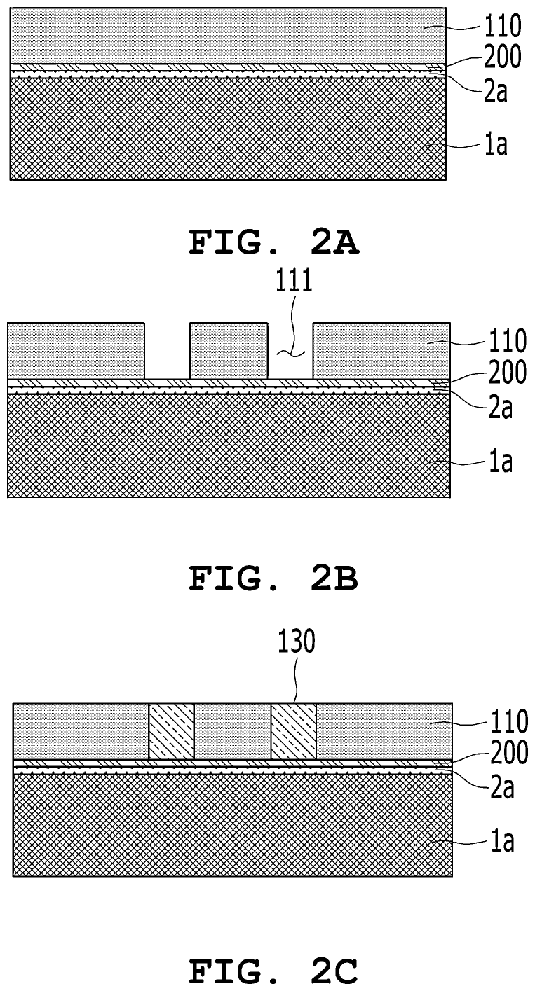

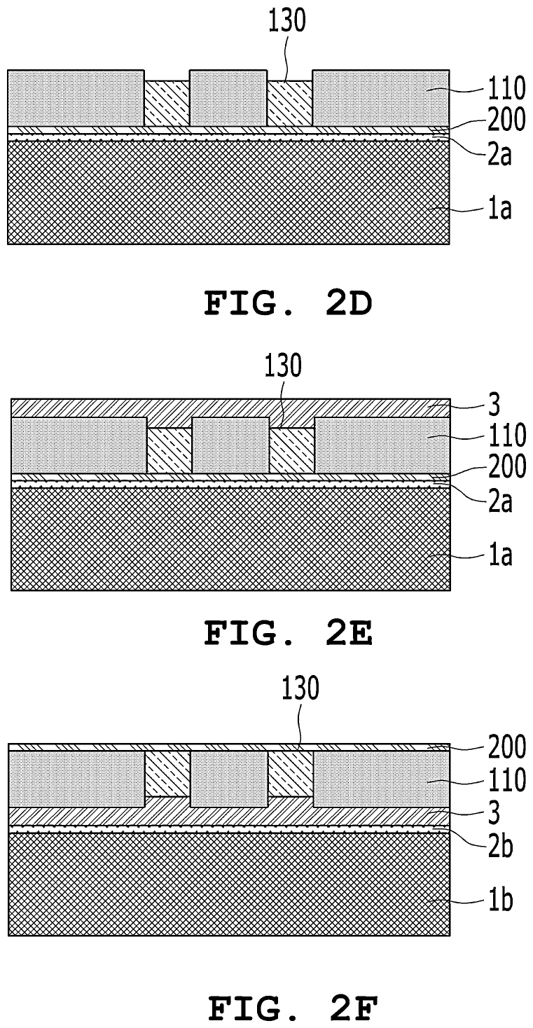

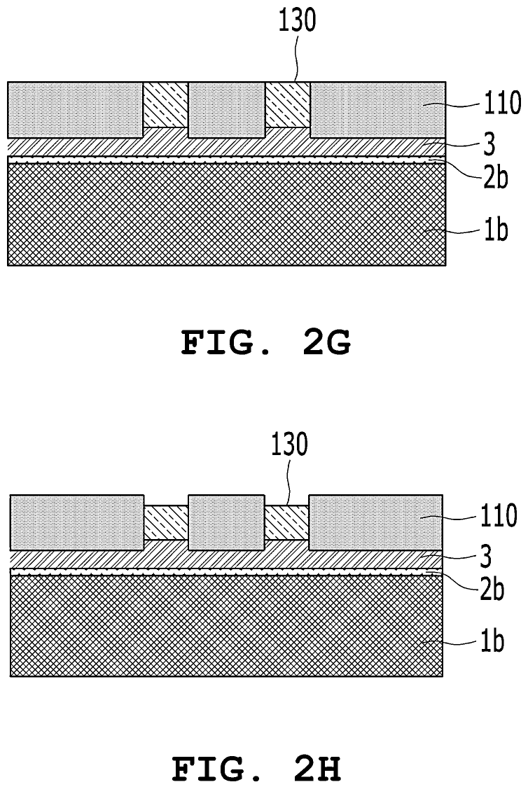

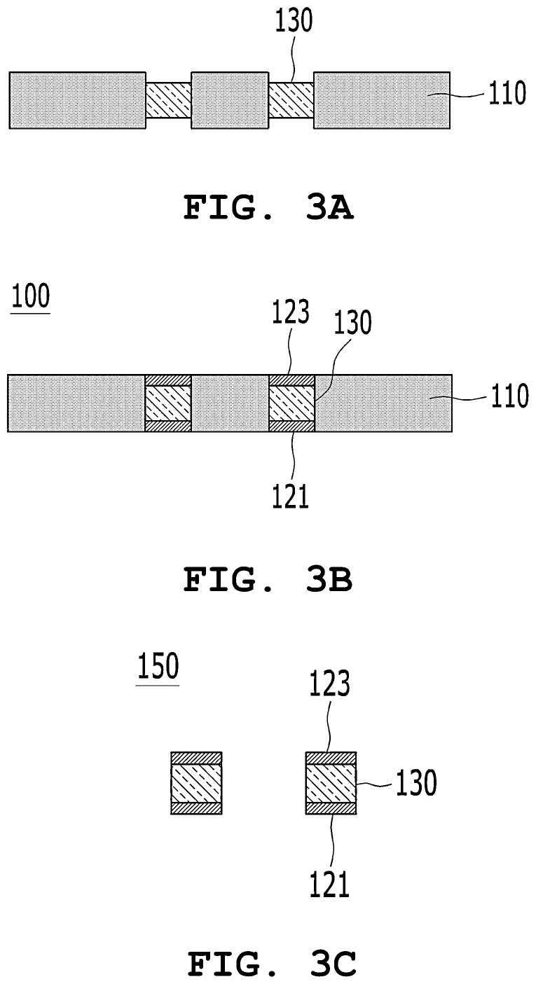

FIG. 1 is a perspective view illustrating the micro bump 150 according to the first embodiment of the present disclosure. FIGS. 2A to 3C are views illustrating a method of manufacturing the micro bump 150 according to the first embodiment of the present disclosure.

Referring to FIG. 1, the micro bump 150 may include an electrically conductive material part 130 and a bonding material part 120 provided on at least a part of an upper portion and a lower portion of the electrically conductive material part 130.

The electrically conductive material part 130 may be made of at least one selected from among Cu, Al, W, Au, Ag, Mo, Ta, and an alloy containing these metals. The bonding material part 120 may be made of at least one selected from among Sn, AgSn, Au, PbSn, SnAgCu, SnAgBi, AuSn, In, InSn, and an alloy containing Sn. For example, the electrically conductive material part 130 may be made of copper (Cu) or an alloy containing copper (Cu) as a main component, and the bonding material part 120 may be made of tin (Sn) or an alloy containing tin (Sn) as a main component.

The electrically conductive material part 130 may be formed by stacking multiple layers of different metals. For example, the electrically conductive material part 130 may be configured such that a metal that has good adhesion to the bonding material part 120 or a first metal that can minimize loss of electrical signals at the interface is located in an area where the electrically conductive material part is in contact with the bonding material part 120, and a second metal that includes copper (Cu) or an alloy containing copper (Cu) as a main component is located in the remaining area. Thereby, the electrically conductive material part 130 may be composed of multiple layers of the first metal and the second metal.

The bonding material part 120 includes a first bonding material part 121 provided on the lower portion of the electrically conductive material part 130 and a second bonding material part 123 provided on the upper portion of the electrically conductive material part 130.

The first bonding material part 121 and the second bonding material part 123 may be made of the same material. Alternatively, the first bonding material part 121 and the second bonding material part 123 may be made of different materials. In addition, the first bonding material part 121 and the second bonding material part 123 may have different melting points.

The micro bump 150 may have a cylindrical shape. However, the shape of the micro bump 150 is not limited thereto. The micro bump 150 may have various shapes including a polygonal prism shape.

A method of manufacturing the micro bump 150 according to the first embodiment of the present disclosure will be described with reference to FIGS. 2A to 3C.

The method of manufacturing the micro bump 150 includes: an electrically conductive material part forming step of forming an electrically conductive material part 130 in a through-hole 111 provided in a body 110 made of an anodic aluminum oxide film; and a bonding material part forming step of forming a bonding material part 120 on at least a part of an upper portion and a lower portion of the electrically conductive material part 130.

First, referring to FIG. 2A, the body 110 made of the anodic aluminum oxide film is bonded to a first temporary substrate 1a with first bonding layer 2a. The first temporary substrate 1a may be a substrate made of a silicon wafer. A seed layer 200 is provided under the body 110 made of the anodic aluminum oxide film. The seed layer 200 is located between the first bonding layer 2a and the body 110 made of the anodic aluminum oxide film.

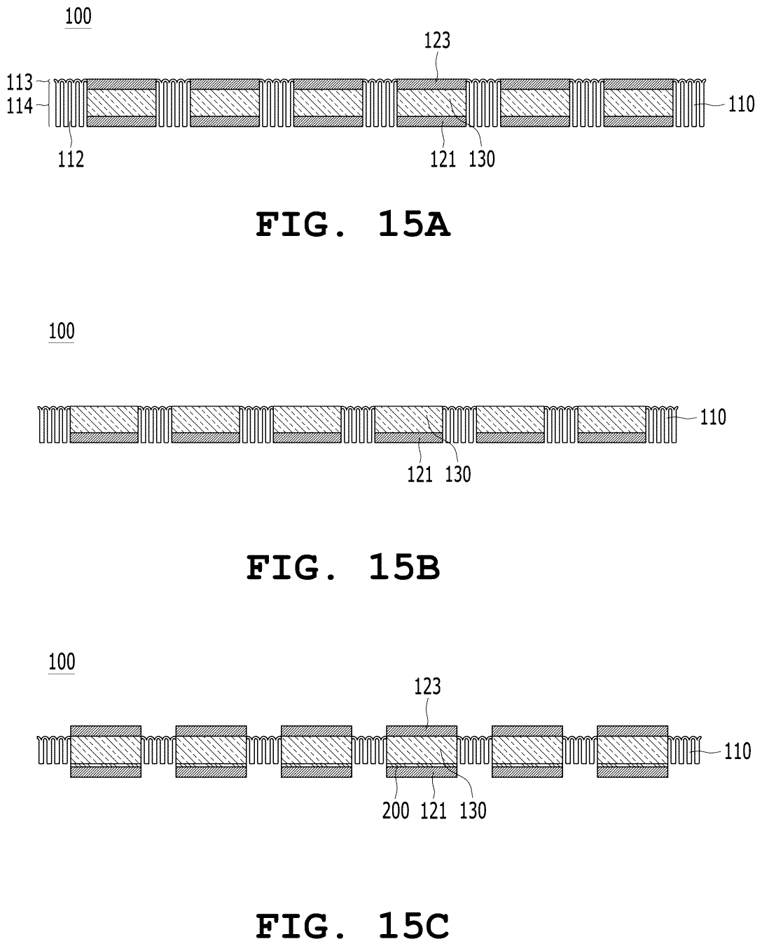

The body 110 made of the anodic aluminum oxide film is manufactured by anodizing a base metal and then removing the base metal. The anodic aluminum oxide film means a film formed by anodizing a metal as a base material, and pores 112 (see FIGS. 15A, 15B, 15C, and 15D) mean holes formed in the process of forming the anodic aluminum oxide film by anodizing the metal. For example, when the metal as the base material is aluminum (Al) or an aluminum alloy, the anodization of the base material forms the anodic aluminum oxide film consisting of anodized aluminum (Al₂O₃) on a surface of the base material. However, the metal is not limited thereto, and includes Ta, Nb, Ti, Zr, Hf, Zn, W, Sb, or an alloy of these metals. The resulting anodic aluminum oxide film includes a barrier layer 113 (see FIGS. 15A, 15B, 15C, and 15D) in which no pores 112 are formed therein vertically, and a porous layer 114 (see FIGS. 15A, 15B, 15C, and 15D) in which pores 112 are formed therein. After removing the base material on which the anodic aluminum oxide film having the barrier layer 113 and the porous layer 114 is formed, only the anodic aluminum oxide film consisting of anodized aluminum (Al₂O₃) remains. The anodic aluminum oxide film may have a structure in which the barrier layer 113 formed during the anodization is removed to expose the top and bottom of the pores 112, or a structure in which the barrier layer 113 formed during the anodization remains to close one of the top and bottom of the pores 112.

The anodic aluminum oxide film has a coefficient of thermal expansion of 2 to 3 ppm/° C. With this range, the anodic aluminum oxide film only undergoes a small amount of thermal deformation due to temperature when exposed to a high temperature environment. Thus, even when the micro bump 150 is manufactured in a high temperature environment, a precise micro bump 150 can be manufactured without thermal deformation.

Since the micro bump 150 according to the embodiment of the present disclosure is manufactured using the body 110 made of the anodic aluminum oxide film instead of a photoresist mold, there is an effect of realizing shape precision and a fine shape, which were limited in realization with the photoresist mold.

Meanwhile, the seed layer 200 is provided on one surface of the body 110 by a deposition method. The seed layer 200 is preferably made of copper (Cu) to improve plating characteristics during electroplating, but is not limited thereto.

Next, referring to FIG. 2B, a plurality of through-holes 111 is formed in the body 110.

The body 110 has the through-holes 111 provided separately from the pores 112 (see FIGS. 15A, 15B, 15C, and 15D) and having a width greater than that of the pores 112. The through-holes 111 may be formed to have a width in the range of several μm to several hundreds of μm. The through-holes 111 may be provided by an etching process. In forming the through-holes 111, the through-holes 111 may be simultaneously formed by a single etching process using an etching solution (e.g., alkali solution) that wet-reacts with the anodic aluminum oxide film. This is advantageous in terms of production speed and manufacturing cost compared to the technology of forming one via hole at one time.

The through-holes 111 may be formed by forming a photoresist on one surface of the body 110, patterning the photoresist to form openings, and then flowing the etching solution through the openings. Thus, the through-holes 111 have a cross-sectional shape that corresponds to the shape of the patterned openings.

Since the through-holes 111 are formed by the etching process using the patterned photoresist as a mask, the cross-sectional shape of the through-holes 111 is not limited, and the through-holes 111 resulting from the reaction of the anodic aluminum oxide film with the etching solution each have a vertical inner wall.

The through-holes 111 may have a circular cross-section. However, the cross-sectional shape of the through-holes 111 is not limited to a circular shape.

Next, referring to FIG. 2C, electrically conductive material parts 130 are formed by electroplating using the seed layer 200.

An electrically conductive material part 130 fills the inside of each of the through-holes 111 having the vertical inner wall and is formed into a column shape. The column-shaped electrically conductive material part 130 has the same cross-sectional area from a lower surface to an upper surface of the body 110. Thus, it is advantageous in terms of efficient electric flow compared to, for example, a spherical or conical micro bump that has a non-vertical inner wall. In the case of an electrically conductive material part in which an inner wall thereof does not have a vertical shape and the cross-sectional area thereof gradually decreases from a lower surface to an upper surface thereof or gradually decreases from a peripheral portion toward a central portion thereof, a thermal and electrical bottleneck section is formed. However, the electrically conductive material part 130 according to the embodiment of the present disclosure has no thermal and electrical bottleneck section because the cross-sectional area thereof is uniform from a lower surface to an upper surface thereof.

After the plating process is completed, a planarization process may be performed. Each protruding electrically conductive material part 130 is removed and planarized through a chemical mechanical polishing (CMP) process.

Next, referring to FIG. 2D, a part of the upper portion of each electrically conductive material part 130 is removed using an etchant that selectively reacts with the material of the electrically conductive material part 130.

Next, referring to FIG. 2E, the upper surface of the body 110 and the upper surface of each electrically conductive material part 130 are covered with a sacrificial layer 3.

Next, referring to FIG. 2F, the first bonding layer 2a is removed by releasing the bonding force of the first bonding layer 2a and then the body in an inverted state is bonded to a second temporary substrate 1b through a second bonding layer 2b.

Next, referring to FIG. 2G, the seed layer 200 is removed.

Next, referring to FIG. 2H, a part of the upper portion (in the drawings) of each electrically conductive material part 130 is removed using an etchant that selectively reacts with the material of the electrically conductive material part 130.

Next, referring to FIG. 3A, the remaining portions are removed except for the body 110 and the electrically conductive material parts 130.

Next, referring to FIG. 3B, a first bonding material part 121 and a second bonding material part 123 are formed on the lower portion and the upper portion of each electrically conductive material part 130. The first bonding material part 121 and the second bonding material part 123 are formed by a deposition method.

With the configuration illustrated in FIG. 3B, an interposer 100 for electrical connection may be formed. The interposer 100 for electrical connection may include a body 110 made of an anodic aluminum oxide film and a micro bump 150 provided in each through-hole 111 of the body 110. The micro bump 150 may be kept fixed in the through-hole 111. The interposer 100 for electrical connection enables a plurality of micro bumps 150 to be transferred collectively. Thus, the use of the interposer 100 for electrical connection can improve the production efficiency of a semiconductor package 400 and/or a multi-layer stacked semiconductor device 500 and/or display, which will be described later.

Next, referring to FIG. 3C, the body 110 made of the anodic aluminum oxide film is removed using an etchant that selectively reacts with the anodic aluminum oxide film to obtain individualized micro bumps 150.

After the plating process is completed, the temperature is raised to a high temperature and pressure is applied to pressurize a metal layer on which the plating process is completed so that the electrically conductive material parts 130 are made denser. When a photoresist is used as a mold, the process of raising the temperature to a high temperature and applying pressure cannot be performed because the photoresist exists around the metal layer after the plating process is completed. On the contrary, according to the embodiment of the present disclosure, since the body 110 made of the anodic aluminum oxide film is provided around the metal layer on which the plating process is completed, even when the temperature is raised to a high temperature, it is possible to densify the electrically conductive material parts 130 with minimized deformation because of the low coefficient of thermal expansion of the anodic aluminum oxide film. Thus, it is possible to obtain the electrically conductive material parts 130 with a higher density compared to the technique using the photoresist as the mold.

The micro bump 150 according to the first embodiment of the present disclosure may be configured in a circular column shape having a circular cross-section. With this, the micro bump 150 has a larger volume than a conventional ball-shaped solder bump and thus has an effect of reducing current density and thermal energy density.

In addition, according to the first embodiment of the present disclosure, it is possible to limit the height of the micro bump 150 to the height of the through-hole 111, thereby reducing a height deviation between a plurality of micro bumps 150.

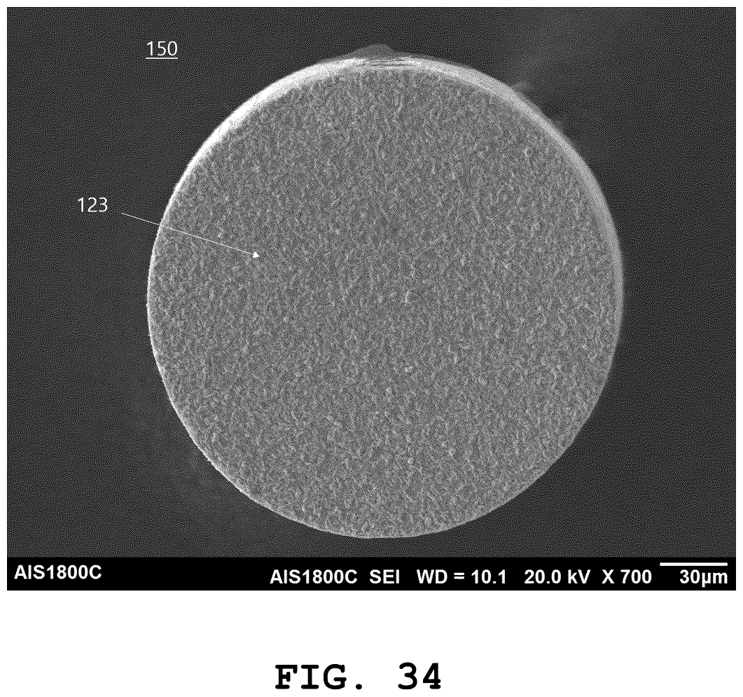

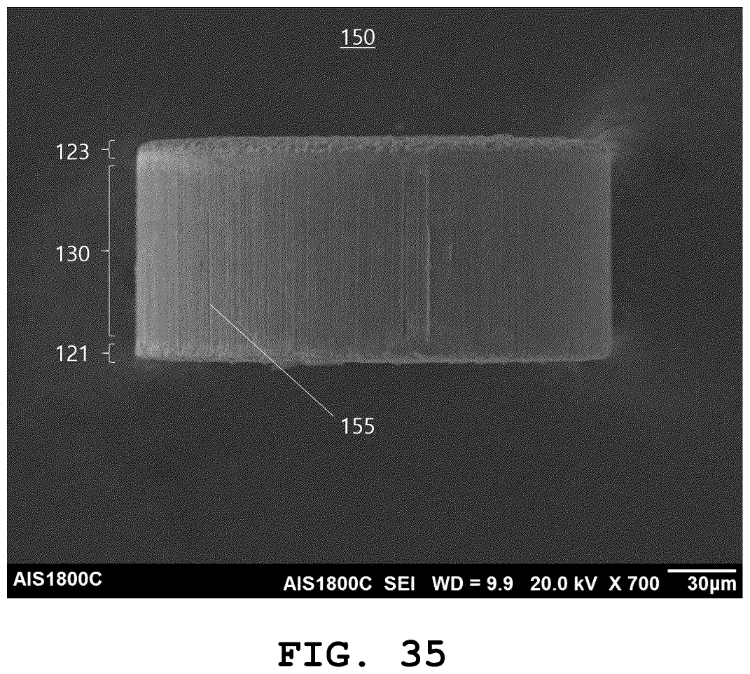

FIGS. 34 and 35 are images illustrating the micro bump 150 according to the first embodiment of the present disclosure, which is formed by stacking the first bonding material part 121, the electrically conductive material part 130, and the second bonding material part 123. FIG. 34 is an image illustrating an upper surface of the micro bump 150, and FIG. 35 is an image illustrating a side surface of the micro bump 150.

The micro bump 150 is composed of the sequentially stacked first bonding material part 121, electrically conductive material part 130, and second bonding material part 123, and has a substantially cylindrical shape.

The micro bump 150 has a height in the range of 70 μm to 200 μm. The electrically conductive material part 130 has a height higher than that of the first bonding material part 121 and higher than that of the second bonding material part 123. Preferably, the first bonding material part 121 and the second bonding material part 123 are formed to have a height in the range of 1 μm to 20 μm, and the electrically conductive material part 130 is formed to have a height in the range of 50 μm to 180 μm. In addition, the micro bump 150 has a diameter in the range of 70 μm to 200 μm. Of course, these dimensions are only an example, and the micro bump 150 may be formed with a smaller dimension.

A fine trench 155 is provided on a side surface of the micro bump 150.

The fine trench 155 is formed on an outer circumferential surface of the micro bump 150. The fine trench 155 is formed on the side surface of the micro bump 150 in the form of a groove extending in the height direction of the micro bump 150.

More specifically, a plurality of fine trenches 155 are provided on a side surface of the electrically conductive material part 130. The fine trenches 155 are provided along the entire circumference of the side surface of the electrically conductive material part 130.

The fine trenches 155 are provided on the side surface of each of the electrically conductive material part 130, the first bonding material part 121, and the second bonding material part 123.

The fine trenches 155 have a depth in the range of 20 nm to 1 μm and a width in the range of 20 nm to 1 μm. Here, as will be described later, because the fine trenches 155 are resulted from the formation of the pores 112 formed during the manufacture of the body 110 made of the anodic aluminum oxide film, the width and the depth of the fine trenches 155 are less than the diameter of the pores 112 formed in the body 110. On the other hand, in the process of forming the through-holes 111 in the body 110, portions of the pores 112 of the body 110 may be crushed by the etching solution to at least partially form a fine trench 155 having a depth greater than the diameter of the pores 112 formed during the anodization.

Since the body 110 includes a large number of pores 112, at least portions of the body 110 are etched to form the through-holes 111, and the first bonding material part 121, the electrically conductive material part 130, and the second bonding material part 123 are formed in each of the through-holes 111, the fine trenches 155 are provided on the side surface of the micro bump 150 as a result of contact between the micro bump and the pores 112 of the body 110.

The fine trenches 155 have a corrugated shape in which peaks and valleys with a depth in the range of 20 nm to 1 μm are repeated in the circumferential direction and thus have an effect of increasing the surface area of the side surface of the micro bump 150. That is, even when the micro bump 150 according to the embodiment of the present disclosure has the same shape and dimensions as a conventional bump, the surface area of the side surface of the micro bump 150 can be further increased by the configuration of the fine trenches 155. With the configuration of the fine trenches 155 formed on the side surface of the micro bump 150, the surface area through which a current flows can be increased by the skin effect, so that the density of the current flowing along the micro bump 150 can be increased, thereby improving electrical characteristics of the micro bump 150. In addition, with the configuration of the fine trenches 155, heat generated in the micro bump 150 can be rapidly dissipated, thereby suppressing a rise in the temperature of the micro bump 150.

### Micro Bump 150 According to Second Embodiment

Next, a micro bump 150 according to a second embodiment of the present disclosure will be described. However, the embodiments described below will be mainly described in terms of characteristic elements in comparison with the micro bump 150 according to the first embodiment, and descriptions of the same or similar elements to the micro bump 150 according to the first embodiment will be omitted.

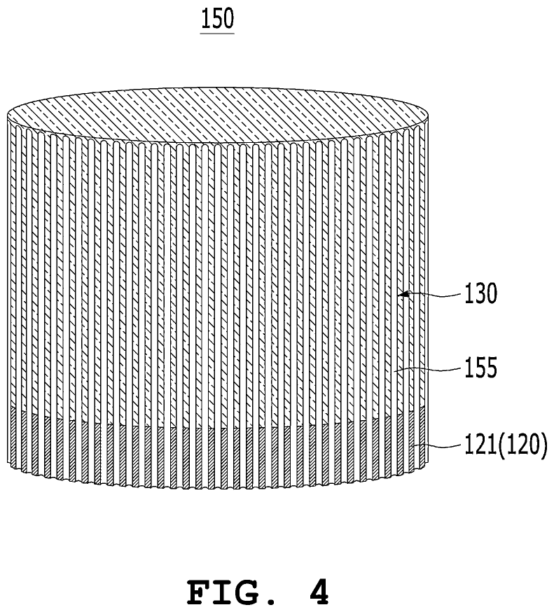

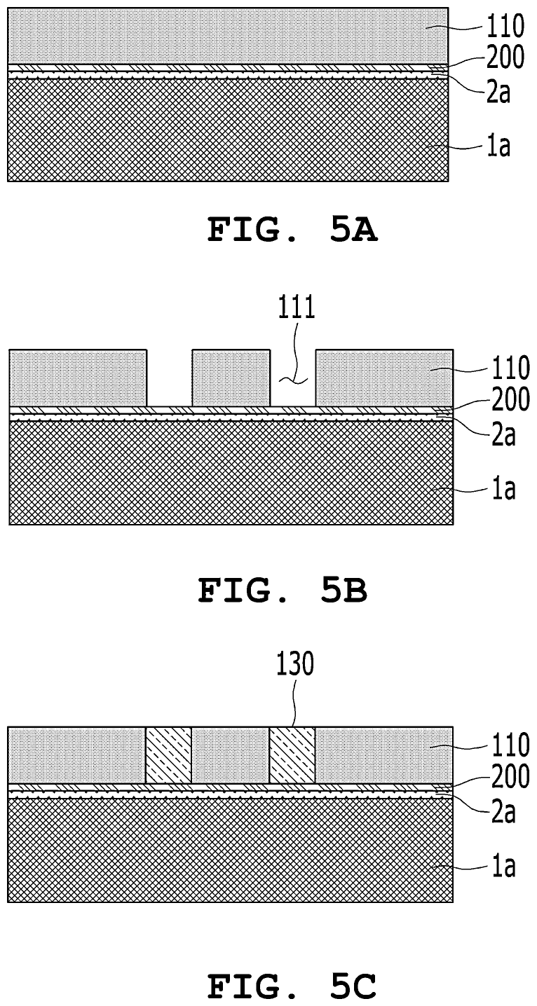

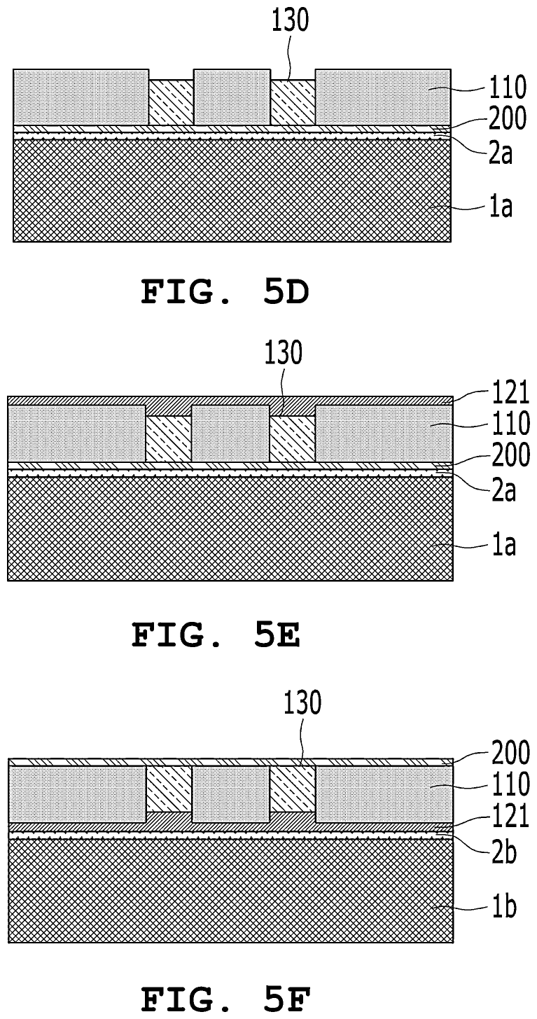

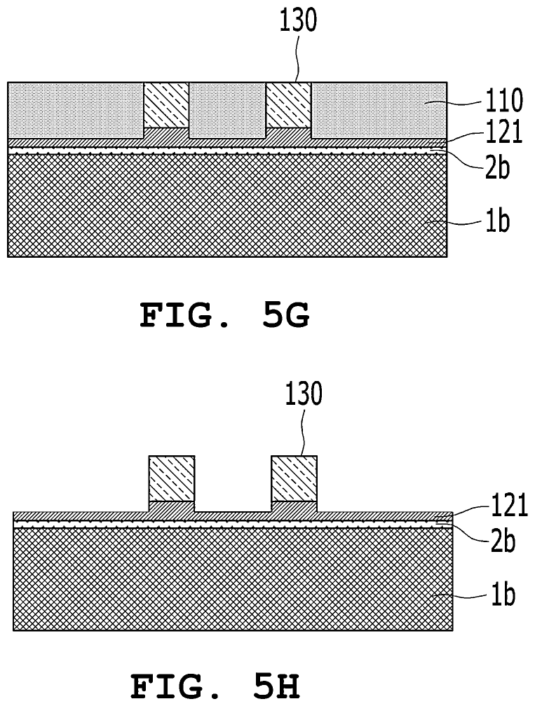

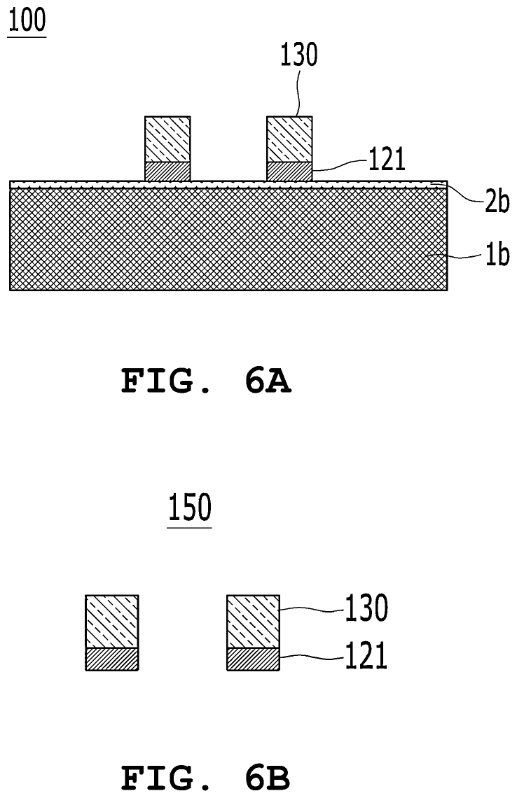

Hereinafter, the micro bump 150 according to the second embodiment of the present disclosure will be described with reference to FIGS. 4 to 6B. FIG. 4 is a perspective view illustrating the micro bump 150 according to the second embodiment of the present disclosure. FIGS. 5A to 6B are views illustrating a method of manufacturing the micro bump 150 according to the second embodiment of the present disclosure.

The micro bump 150 according to the second embodiment is different from the micro bump 150 according to the first embodiment in which the electrically conductive material part 130 is also provided with the second bonding material part 123 on the lower portion thereof in that an electrically conductive material part 130 is provided only with a first bonding material part 121 on an upper portion thereof.

The method of manufacturing the micro bump 150 according to the second embodiment of the present disclosure will be described with reference to FIGS. 5A to 6B.

First, referring to FIG. 5A, a body 110 made of an anodic aluminum oxide film is bonded to a first temporary substrate 1a with a first bonding layer 2a. The first temporary substrate 1a may be a substrate made of a silicon wafer. A seed layer 200 is provided under the body 110 made of the anodic aluminum oxide film. The seed layer 200 is located between the first bonding layer 2a and the body 110 made of the anodic aluminum oxide film. Meanwhile, the seed layer 200 is provided on one surface of the body 110 by a deposition method. The seed layer 200 is preferably made of copper (Cu) to improve plating characteristics during electroplating, but is not limited thereto.

Next, referring to FIG. 5B, a plurality of through-holes 111 is formed in the body 110. The through-holes 111 may have a circular cross-section. However, the cross-sectional shape of the through-holes 111 is not limited to a circular shape.

Next, referring to FIG. 5C, electrically conductive material parts 130 are formed by electroplating using the seed layer 200. After the plating process is completed, a planarization process may be performed. Each protruding electrically conductive material part 130 is removed and planarized through a chemical mechanical polishing (CMP) process.

Next, referring to FIG. 5D, a part of the upper portion of each electrically conductive material part 130 is removed using an etchant that selectively reacts with the material of the electrically conductive material part 130.

Next, referring to FIG. 5E, an upper surface of the body 110 and an upper surface of each electrically conductive material part 130 are covered with the metal constituting the first bonding material part 121.

Next, referring to FIG. 5F, the first bonding layer 2a is removed by releasing the bonding force of the first bonding layer 2a and then the body in an inverted state is bonded to a second temporary substrate 1b through a second bonding layer 2b. Here, the second temporary substrate 1b may be a glass substrate, and the second bonding layer 2b may be a bonding layer that can be released from the bonding force in response to ultraviolet light (UV light).

Next, referring to FIG. 5G, the seed layer 200 is removed.

Next, referring to FIG. 5H, the body 111 made of the anodic aluminum oxide film is removed using an etchant that selectively reacts with the anodic aluminum oxide film.

Next, referring to FIG. 6A, the remaining portions are removed except for the first bonding material part 121 located under the electrically conductive material part 130.

With the configuration illustrated in FIG. 6A, an interposer 100 for electrical connection may be formed. The interposer 100 for electrical connection may include a plurality of micro bumps 150, a second temporary substrate 2b, and a second bonding layer 2b provided on the second temporary substrate 2b to secure the micro bumps 150 to the second temporary substrate 2b. The micro bumps 150 may be kept bonded to the second temporary substrate 2b through the second bonding layer 2b.

The interposer 100 for electrical connection enables a plurality of micro bumps 150 to be transferred collectively. Thus, the use of the interposer 100 for electrical connection can improve the production efficiency of a semiconductor package 400 and/or a multi-layer stacked semiconductor device 500 and/or display, which will be described later.

Next, referring to FIG. 6B, individualized micro bumps 150 are obtained by releasing the bonding force between the micro bumps 150 and the second bonding layer 2b. When the second bonding layer 2b is a bonding layer that can be released from the bonding force in response to ultraviolet light (UV light), the micro bumps 150 may be removed from the second temporary substrate 1b by radiating UV light.

### Micro Bump 150 According to Third Embodiment

Next, a micro bump 150 according to a third embodiment of the present disclosure will be described. However, the embodiments described below will be mainly described in terms of characteristic elements in comparison with the micro bump 150 according to the first embodiment, and descriptions of the same or similar elements to the micro bump 150 according to the first embodiment will be omitted.

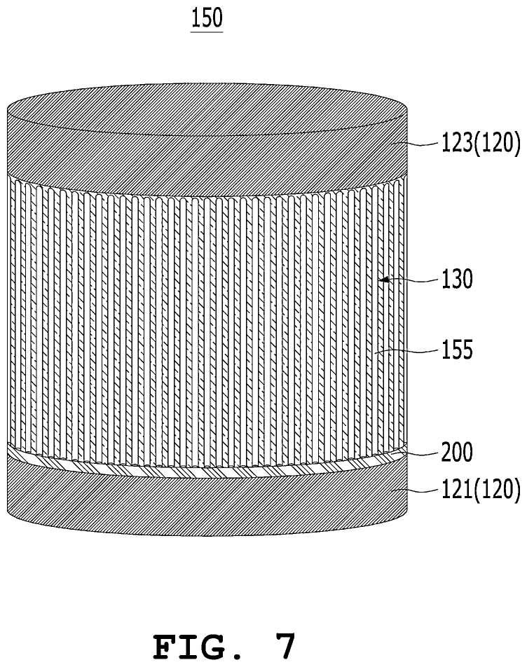

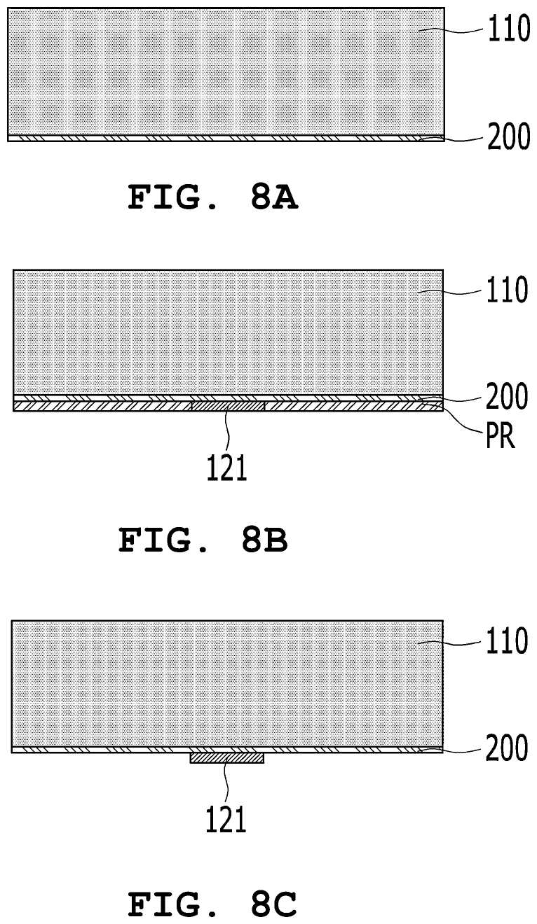

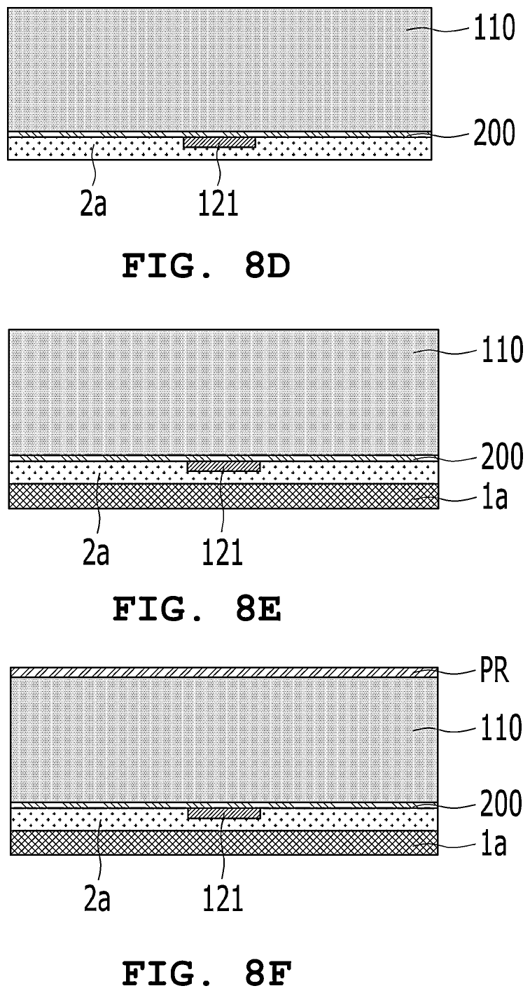

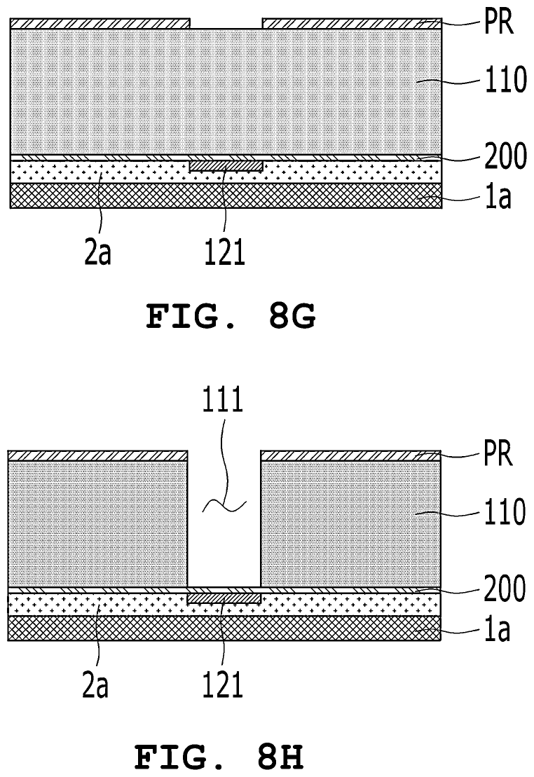

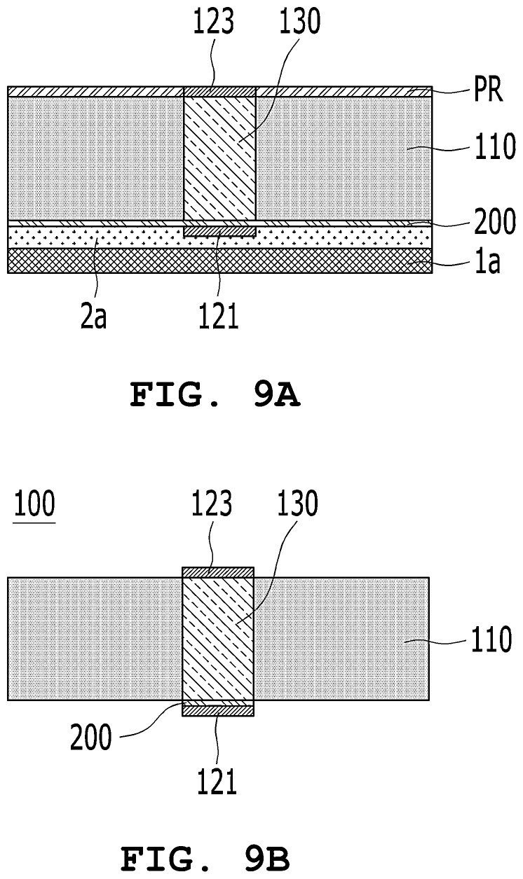

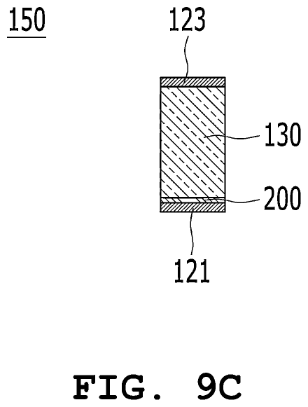

Hereinafter, the micro bump 150 according to the third embodiment of the present disclosure will be described with reference to FIGS. 7 to 9C. FIG. 7 is a perspective view illustrating the micro bump 150 according to the third embodiment of the present disclosure. FIGS. 8A to 9C are views illustrating a method of manufacturing the micro bump 150 according to the third embodiment of the present disclosure.

The micro bump 150 according to the third embodiment is different from the micro bump 150 according to the first embodiment in that a seed layer 200 is provided between an electrically conductive material part 130 and a first bonding material part 121.

The method of manufacturing the micro bump 150 according to the third embodiment of the present disclosure will be described with reference to FIGS. 8A to 9C.

First, referring to FIG. 8A, the seed layer 200 is formed under a body 110 made of an anodic aluminum oxide film. The seed layer 200 is provided on one surface of the body 110 by a deposition method. The seed layer 200 is preferably made of copper (Cu) to improve plating characteristics during electroplating, but is not limited thereto. Meanwhile, in order to prevent a whisker phenomenon caused by diffusion of the first bonding material part 121, the seed layer 200 may be made of a component containing Ni, Fe, or the like.

Next, referring to FIG. 8B, a photoresist PR is formed under the seed layer 200 and patterned to form an opening, and then the opening is filled with a metal to form the first bonding material part 121. The first bonding material part 121 may be formed by electroplating using the seed layer 200 or may formed by a deposition method.

Next, referring to FIG. 8C, the photoresist PR in the previous step is removed.

Next, referring to FIG. 8D, a first bonding layer 2a is formed to cover both a lower surface of the seed layer 200 and a lower surface of the first bonding material part 121.

Next, referring to FIG. 8E, a first temporary substrate 1a is placed under the first bonding layer 2a and bonded to the first bonding layer 2a.

Next, referring to FIG. 8F, a photoresist PR is formed.

Next, referring to FIG. 8G, the photoresist PR is patterned to form an opening.

Next, referring to FIG. 8H, a through-hole 111 is formed in the body 110 by selectively etching only the anodic aluminum oxide film by wet etching through the opening.

Next, referring to FIG. 9A, the electrically conductive material part 130 is formed, and a second bonding material part 123 is formed on the electrically conductive material part 130. The electrically conductive material part 130 may be formed by electroplating using the seed layer 200. The second bonding material part 123 may be formed by electroplating using the electrically conductive material part 130 or may be formed by a deposition method.

As a result, the electrically conductive material part 130 and the second bonding material part 123 are sequentially stacked inside the through-hole 111 of the body 110.

The electrically conductive material part 130 and the second bonding material part 123 sequentially fill the inside of the through-hole 111 having a vertical inner wall to form a column-shaped micro bump 150. Afterwards, the photoresist PR, the first temporary substrate 1a, and the first bonding layer 2a are removed.

Next, referring to FIG. 9B, with the configuration illustrated in FIG. 9B, an interposer 100 for electrical connection may be formed. The interposer 100 for electrical connection may include a body 110 made of an anodic aluminum oxide film and a micro bump 150 provided in a through-hole 111 of the body 110. More specifically, a first bonding material part 121 of the micro bump 150 and a seed layer 200 are formed to protrude from a lower portion of the body 110, and a second bonding material part 123 of the micro bump is formed to protrude from an upper portion of the body 110. Since the first and second bonding material parts 121 and 123 protrude from surfaces of the body 110, when the micro bump 150 is bonded to an object, interference between the body 110 and the object can be minimized. The micro bump 150 may be kept fixed in the through-hole 111. The interposer 100 for electrical connection enables a plurality of micro bumps 150 to be transferred collectively. Thus, the use of the interposer 100 for electrical connection can improve the production efficiency of a semiconductor package 400 and/or a multi-layer stacked semiconductor device 500 and/or display, which will be described later.

Next, referring to FIG. 9C, the body 110 made of the anodic aluminum oxide film is removed using an etchant that selectively reacts with the anodic aluminum oxide film to obtain an individualized micro bump 150.

### Micro Bump 150 According to Fourth Embodiment

Next, a micro bump to a fourth 150 according embodiment of the present disclosure will be described. However, the embodiments described below will be mainly described in terms of characteristic elements in comparison with the micro bump 150 according to the first embodiment, and descriptions of the same or similar elements to the micro bump 150 according to the first embodiment will be omitted.

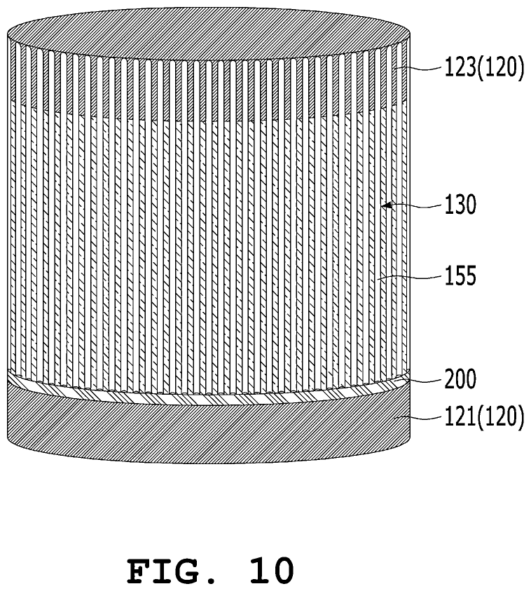

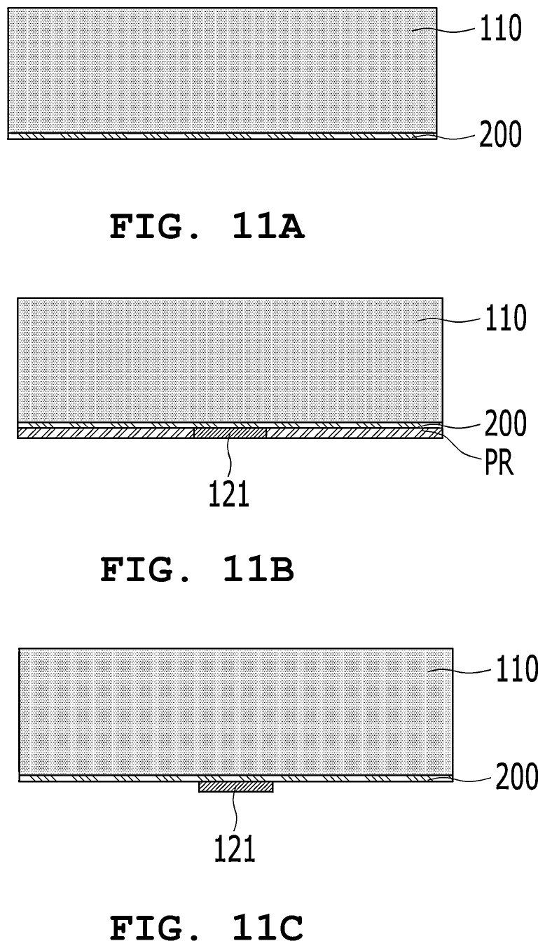

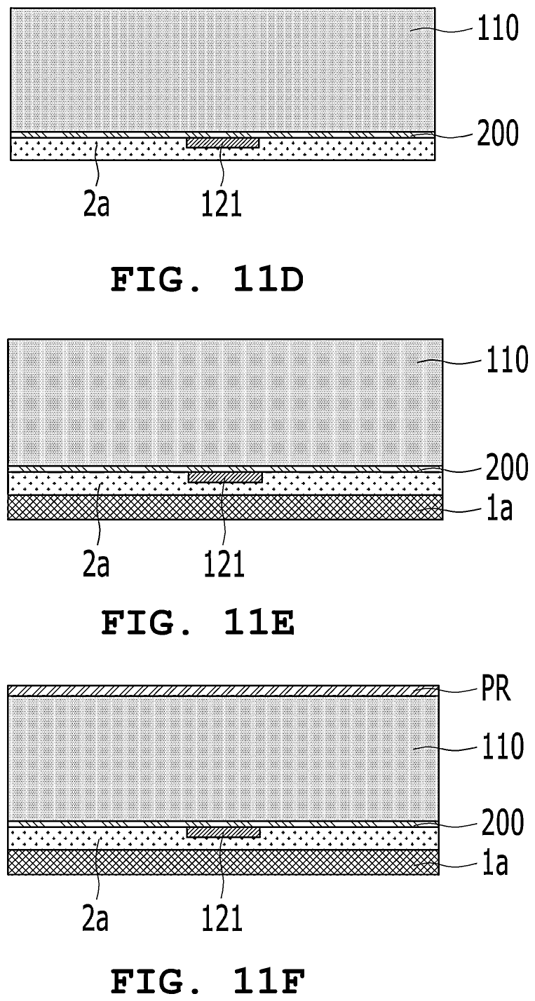

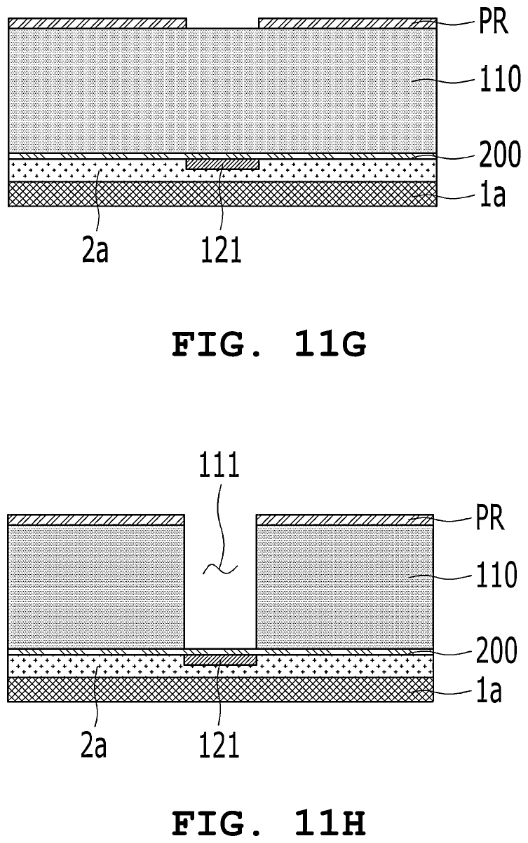

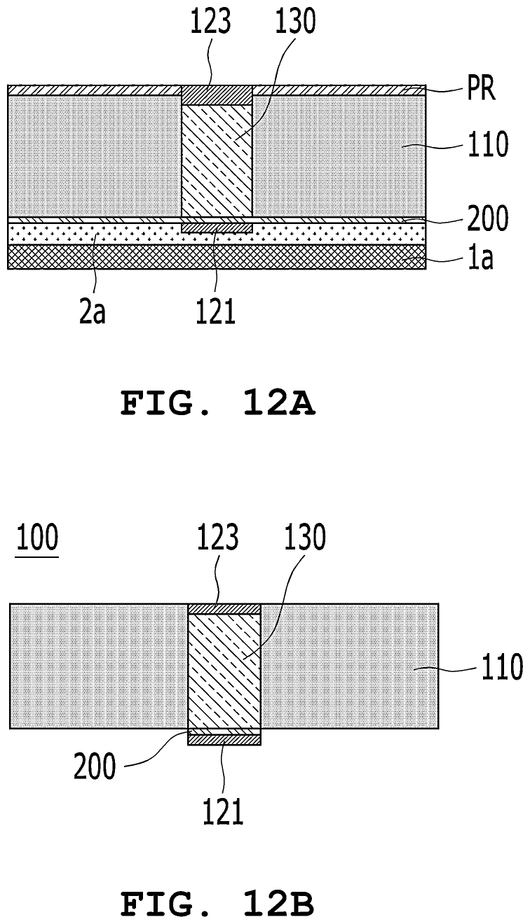

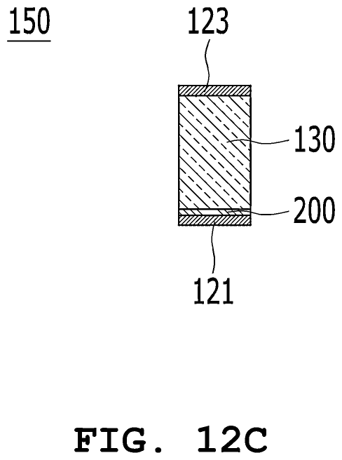

Hereinafter, the micro bump 150 according to the fourth embodiment of the present disclosure will be described with reference to FIGS. 10 to 12C. FIG. 10 is a perspective view illustrating the micro bump 150 according to the fourth embodiment of the present disclosure. FIGS. 11A to 12C are views illustrating a method of manufacturing the micro bump 150 according to the fourth embodiment of the present disclosure.

The micro bump 150 according to the fourth embodiment is different from the micro bump 150 according to the first embodiment in that a seed layer 200 is provided between an electrically conductive material part 130 and a first bonding material part 121. In addition, the micro bump 150 according to the fourth embodiment is different from the micro bump 150 according to the first embodiment in that a plurality of fine trenches 155 is also provided in a second bonding material part 123.

The method of manufacturing the micro bump 150 according to the fourth embodiment of the present disclosure will be described with reference to FIGS. 11A to 12C.

First, referring to FIG. 11A, the seed layer 200 is formed under a body 110 made of an anodic aluminum oxide film. The seed layer 200 is provided on one surface of the body 110 by a deposition method. The seed layer 200 is preferably made of copper (Cu) to improve plating characteristics during electroplating, but is not limited thereto.

Next, referring to FIG. 11B, a photoresist PR is formed under the seed layer 200 and patterned to form an opening, and then the opening is filled with a metal to form the first bonding material part 121.

Next, referring to FIG. 11C, the photoresist PR in the previous step is removed.

Next, referring to FIG. 11D, a first bonding layer 2a is formed to cover both a lower surface of the seed layer 200 and a lower surface of the first bonding material part 121.

Next, referring to FIG. 11E, a first temporary substrate 1a is placed under the first bonding layer 2a and bonded to the first bonding layer 2a.

Next, referring to FIG. 11F, a photoresist PR is formed.

Next, referring to FIG. 11G, the photoresist PR is patterned to form an opening.

Next, referring to FIG. 11H, a through-hole 111 is formed in the body 110 by selectively etching only the anodic aluminum oxide film by wet etching through the opening.

Next, referring to FIG. 12A, the electrically conductive material part 130 is formed, and a second bonding material part 123 is formed on the electrically conductive material part 130. The electrically conductive material part 130 may be formed by electroplating using the seed layer 200. The second bonding material part 123 may be formed by electroplating using the electrically conductive material part 130 or may be formed by a deposition method. As a result, the electrically conductive material part 130 and the second bonding material part 123 are sequentially stacked inside the through-hole 111 of the body 110.

In this case, the electrically conductive material part 130 is formed to have a lower height than the body 110 by controlling the electroplating time and/or current density. This is different from the manufacturing method according to the third embodiment in that the height of the electrically conductive material part 130 is lower than that of the body 110. As a result, the fine trenches 155 are also provided in a side surface of the second bonding material part 123.

Afterwards, the photoresist PR is removed, and the protruding second bonding material part 123 is removed and planarized through a chemical mechanical polishing (CMP) process.

Next, referring to FIG. 12B, with the configuration illustrated in FIG. 12B, an interposer 100 for electrical connection may be formed. The interposer 100 for electrical connection may include a body 110 made of an anodic aluminum oxide film and a micro bump 150 provided in a through-hole 111 of the body 110. More specifically, a first bonding material part 121 of the micro bump 150 and a seed layer 200 are formed to protrude from a lower portion of the body 110, and a second bonding material part 123 of the micro bump is formed not to protrude from an upper portion of the body 110. Since the first bonding material part 121 protrudes from a lower surface of the body 110, when the micro bump 150 is bonded to an object, interference between the body 110 and the object can be minimized. The micro bump 150 may be kept fixed in the through-hole 111. The interposer 100 for electrical connection enables a plurality of micro bumps 150 to be transferred collectively. Thus, the use of the interposer 100 for electrical connection can improve the production efficiency of a semiconductor package 400 and/or a multi-layer stacked semiconductor device 500 and/or display, which will be described later.

Next, referring to FIG. 12C, the body 110 made of the anodic aluminum oxide film is removed using an etchant that selectively reacts with the anodic aluminum oxide film to obtain an individualized micro bump 150.

### Micro Bump 150 According to Fifth Embodiment

Next, a micro bump 150 according to a fifth embodiment of the present disclosure will be described. However, the embodiments described below will be mainly described in terms of characteristic elements in comparison with the micro bump 150 according to the first embodiment, and descriptions of the same or similar elements to the micro bump 150 according to the first embodiment will be omitted.

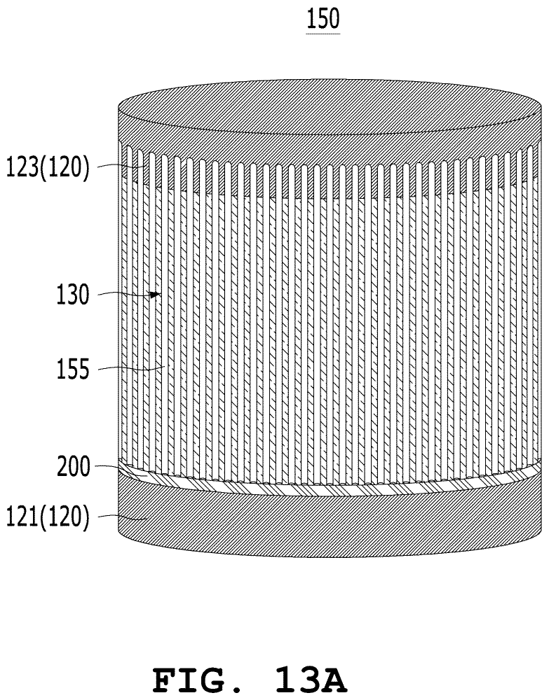

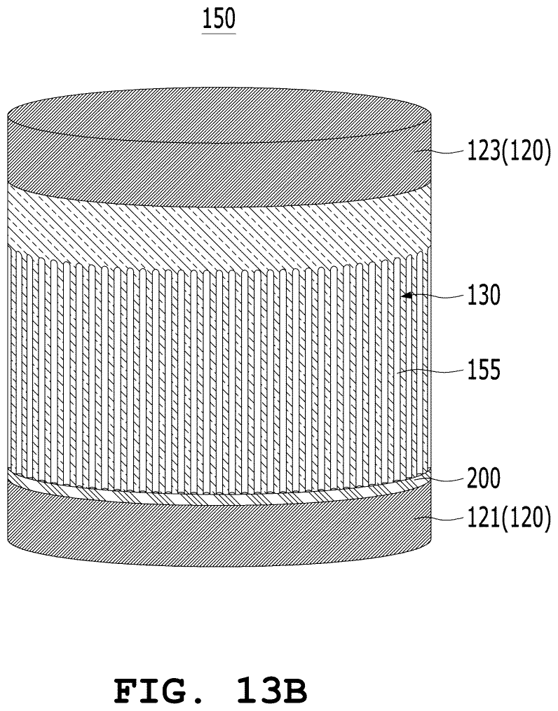

Hereinafter, the micro bump 150 according to the fifth embodiment of the present disclosure will be described with reference to FIG. 13A. FIG. 13A is a perspective view illustrating the micro bump 150 according fifth embodiment of the present disclosure.

The micro bump 150 according to the fifth embodiment is different from the micro bump 150 according to the first embodiment in that a seed layer 200 is provided between an electrically conductive material part 130 and a first bonding material part 121. In addition, the micro bump 150 according to the fifth embodiment is different from the micro bump 150 according to the first embodiment in that a plurality of fine trenches 155 is also provided on a part of a side surface of a second bonding material part 123.

The fine trenches 155 provided in the side surface of the second bonding material part 123 are formed by extending a plurality of fine trenches 155 provided in a side surface of the electrically conductive material part 130, and are formed only at a partial height of the second bonding material part 123.

### Micro Bump 150 According to Sixth Embodiment

Next, a micro bump 150 according to a sixth embodiment of the present disclosure will be described. However, the embodiments described below will be mainly described in terms of characteristic elements in comparison with the micro bump 150 according to the first embodiment, and descriptions of the same or similar elements to the micro bump 150 according to the first embodiment will be omitted.

Hereinafter, the micro bump 150 according to the sixth embodiment of the present disclosure will be described with reference to FIG. 13B. FIG. 13B is a perspective view illustrating the micro bump 150 according to the sixth embodiment of the present disclosure.

The micro bump 150 according to the sixth embodiment is different from the micro bump 150 according to the first embodiment in that a seed layer 200 is provided between an electrically conductive material part 130 and a first bonding material part 121. In addition, the micro bump 150 according to the sixth embodiment is different from the micro bump 150 according to the first embodiment in that a plurality of fine trenches 155 is only provided on a part of a side surface of the electrically conductive material part 130.

The fine trenches 155 provided in the side surface of the electrically conductive material part 130 are formed only at a partial height of the electrically conductive material part 130.

### Micro Bump 150 According to Seventh Embodiment

Next, a micro bump 150 according to a seventh embodiment of the present disclosure will be described. However, the embodiments described below will be mainly described in terms of characteristic elements in comparison with the micro bump 150 according to the first embodiment, and descriptions of the same or similar elements to the micro bump 150 according to the first embodiment will be omitted.

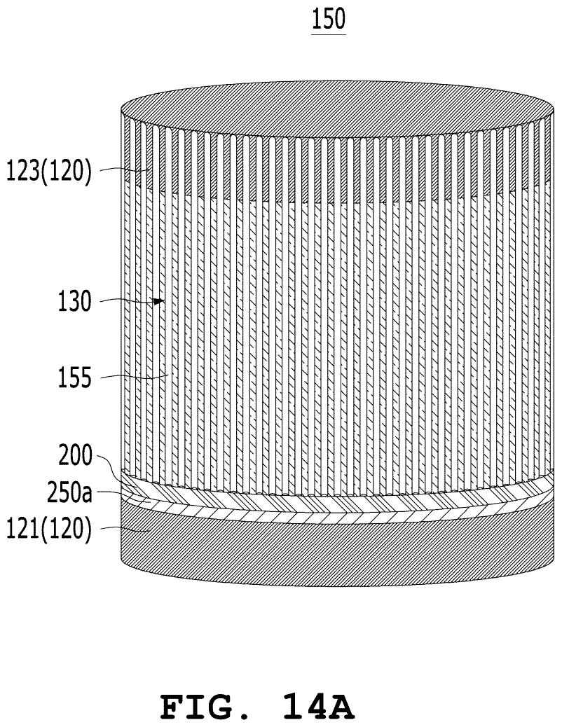

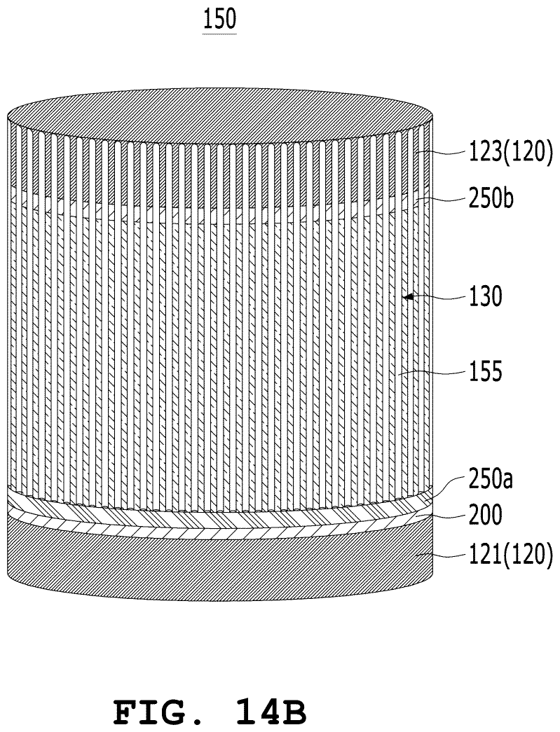

Hereinafter, the micro bump 150 according to the seventh embodiment of the present disclosure will be described with reference to FIG. 14A. FIG. 14A is a perspective view illustrating the micro bump 150 according to the seventh embodiment of the present disclosure.

The micro bump 150 according to the seventh embodiment is different from the micro bump 150 according to the first embodiment in that a seed layer 200 and a lower functional layer 250a are provided between an electrically conductive material part 130 and a first bonding material part 121. In addition, the micro bump 150 according to the fourth embodiment is different from the micro bump 150 according to the first embodiment in that a plurality of fine trenches 155 is also provided in a second bonding material part 123.

The lower functional layer 250a is a layer added to improve the electrical, physical, or chemical characteristics of the micro bump 150. In order to prevent a whisker phenomenon caused by diffusion of the first bonding material part 121, the lower functional layer 250a is provided between the seed layer 200 and the first bonding material part 121, and may be made of a component containing Ni, Fe, or the like.

Meanwhile, modified examples of a plurality of fine trenches 155 according to the seventh embodiment include: a configuration in which a plurality of fine trenches 155 is provided only in an electrically conductive material part 130, but is provided at at least a partial height of the electrically conductive material part 130; a configuration in which a plurality of fine trenches 155 is provided in a first bonding material part 121, a seed layer 200, a functional layer 250, an electrically conductive material part 130, and a second bonding material part 123, but is provided at at least a partial height of the first bonding material part 121; a configuration in which a plurality of fine trenches 155 is provided in a first bonding material part 121, a seed layer 200, a functional layer 250, an electrically conductive material part 130, and a second bonding material part 123, but is provided at at least a partial height of the second bonding material part 123; a configuration in which a plurality of fine trenches 155 is provided in a first bonding material part 121, a seed layer 200, a functional layer 250, and an electrically conductive material part 130, but is provided at at least a partial height of the first bonding material part 121; and a configuration in which a plurality of fine trenches 155 is provided in a first bonding material part 121, a seed layer 200, a functional layer 250, and an electrically conductive material part 130, but is provided at at least a partial height of the electrically conductive material part 130.

### Micro Bump 150 According to Eighth Embodiment

Next, a micro bump 150 according to an eighth embodiment of the present disclosure will be described. However, the embodiments described below will be mainly described in terms of characteristic elements in comparison with the micro bump 150 according to the first embodiment, and descriptions of the same or similar elements to the micro bump 150 according to the first embodiment will be omitted.

Hereinafter, the micro bump 150 according to the eighth embodiment of the present disclosure will be described with reference to FIG. 14B. FIG. 14B is a perspective view illustrating the micro bump 150 according to the eighth embodiment of the present disclosure.

The micro bump 150 according to the eighth embodiment is different from the micro bump 150 according to the first embodiment in that a seed layer 200 and a lower functional layer 250a are provided between an electrically conductive material part 130 and a first bonding material part 121 and an upper functional layer 250b is provided between the electrically conductive material part 130 and a second bonding material part 123. In addition, the micro bump 150 according to the eighth embodiment is different from the micro bump 150 according to the first embodiment in that a plurality of fine trenches 155 is also provided in the second bonding material part 123.

The lower functional layer 250a is a layer added to improve the electrical, physical, or chemical characteristics of the micro bump 150. In order to prevent a whisker phenomenon caused by diffusion of the first bonding material part 121, the lower functional layer 250a is provided between the seed layer 200 and the first bonding material part 121, and may be made of a component containing Ni, Fe, or the like. In addition, the upper functional layer 250b is a layer added to improve the electrical, physical, or chemical characteristics of the micro bump 150. In order to prevent a whisker phenomenon caused by diffusion of the second bonding material part 123, the upper functional layer 250b is provided between the electrically conductive material part 130 and the first bonding material part 121, and may be made of a component containing Ni, Fe, or the like.

A modified example of the eighth embodiment includes a configuration in which a lower functional layer 250a is not provided and only an upper functional layer 250b is provided.

Meanwhile, modified examples of a plurality of fine trenches 155 according to the eighth embodiment include: a configuration in which a plurality of fine trenches 155 is provided only in an electrically conductive material part 130, but is provided at at least a partial height of the electrically conductive material part 130; a configuration in which a plurality of fine trenches 155 is provided in a first bonding material part 121, a seed layer 200, a functional layer 250, an electrically conductive material part 130, and a second bonding material part 123, but is provided at at least a partial height of the first bonding material part 121; a configuration in which a plurality of fine trenches 155 is provided in a first bonding material part 121, a seed layer 200, a functional layer 250, an electrically conductive material part 130, and a second bonding material part 123, but is provided at at least a partial height of the second bonding material part 123; a configuration in which a plurality of fine trenches 155 is provided in a first bonding material part 121, a seed layer 200, a functional layer 250, and an electrically conductive material part 130, but is provided at at least a partial height of the first bonding material part 121; and a configuration in which a plurality of fine trenches 155 is provided in a first bonding material part 121, a seed layer 200, a functional layer 250, and an electrically conductive material part 130, but is provided at at least a partial height of the electrically conductive material part 130.

In the micro bumps 150 according to the seventh and eighth embodiments, the functional layers 250a and 250b are between the electrically conductive material part 130 and the bonding material part 120 to improve the electrical, physical, or chemical characteristics of the micro bumps 150. In the previous description, the function to achieve the purpose of preventing the whisker phenomenon was described as an example, but the function of the functional layers 250a and 250b is not limited thereto.

Meanwhile, although the configuration of the micro bumps 150 has been described separately for the first to eighth embodiments, embodiments in which the configurations of each embodiment are combined are also included in exemplary embodiments of the present disclosure.

### Interposer 100 for Electrical Connection

Next, interposers 100 for electrical connection according to embodiments of the present disclosure will be described hereinafter.

Referring to FIG. 15A, an interposer 100 for electrical connection may include a body 110 made of an anodic aluminum oxide film and a micro bump 150 provided in each through-hole 123 of the body 110. The micro bump 150 may be kept fixed in the through-hole 111. The micro bump 150 includes an electrically conductive material part 130, a first bonding material part 121 provided on a lower portion of the electrically conductive material part 130, and a second bonding material part 123 provided on an upper portion of the electrically conductive material part 130. The first bonding material part 121 does not protrude from a lower surface of the body 110, and the second bonding material part 123 also does not protrude from an upper surface of the body 110.

Referring to FIG. 15B, an interposer 100 for electrical connection may include a body 110 made of an anodic aluminum oxide film and a micro bump 150 provided in each through-hole 123 of the body 110. The micro bump 150 may be kept fixed in the through-hole 111. The micro bump 150 includes an electrically conductive material part 130 and a first bonding material part 121 provided on a lower portion of the electrically conductive material part 130. The first bonding material part 121 does not protrude from a lower surface of the body 110.

Referring to FIG. 15C, an interposer 100 for electrical connection may include a body 110 made of an anodic aluminum oxide film and a micro bump 150 provided in each through-hole 123 of the body 110. The micro bump 150 may be kept fixed in the through-hole 111. The micro bump 150 includes an electrically conductive material part 130, a first bonding material part 121 provided on a lower portion of the electrically conductive material part 130, a second bonding material part 123 provided on an upper portion of the electrically conductive material part 130, and a seed layer 200 provided between the first bonding material part 121 and the electrically conductive material part 130. The first bonding material part 121 and the seed layer 200 are formed to protrude from a lower surface of the body 110, and the second bonding material part 123 is formed to protrude from an upper surface of the body 110.

Referring to FIG. 15D, an interposer 100 for electrical connection may include a body 110 made of an anodic aluminum oxide film and a micro bump 150 provided in each through-hole 123 of the body 110. The micro bump 150 may be kept fixed in the through-hole 111. The micro bump 150 includes an electrically conductive material part 130, a first bonding material part 121 provided on a lower portion of the electrically conductive material part 130, a second bonding material part 123 provided on an upper portion of the electrically conductive material part 130, and a seed layer 200 provided between the first bonding material part 121 and the electrically conductive material part 130. The first bonding material part 121 and the seed layer 200 are formed to protrude from a lower surface of the body 110, and the second bonding material part 123 is formed not to protrude from an upper surface of the body 110.

Meanwhile, the interposers 100 for electrical connection described above include the configuration of the above-described micro bumps 150 according to the first to eighth embodiments and the embodiments in which the configurations of each embodiment are combined.

### Semiconductor Package 400

Hereinafter, a semiconductor package 400 having micro bump 150 will be described.

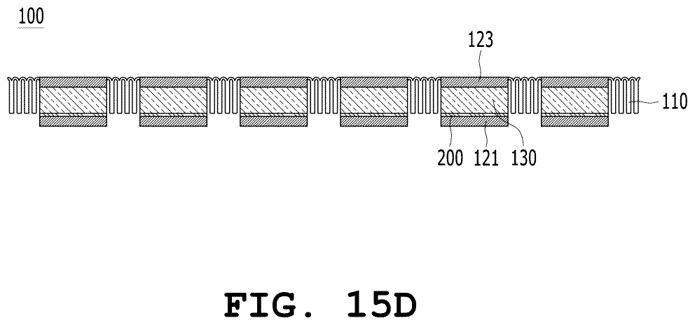

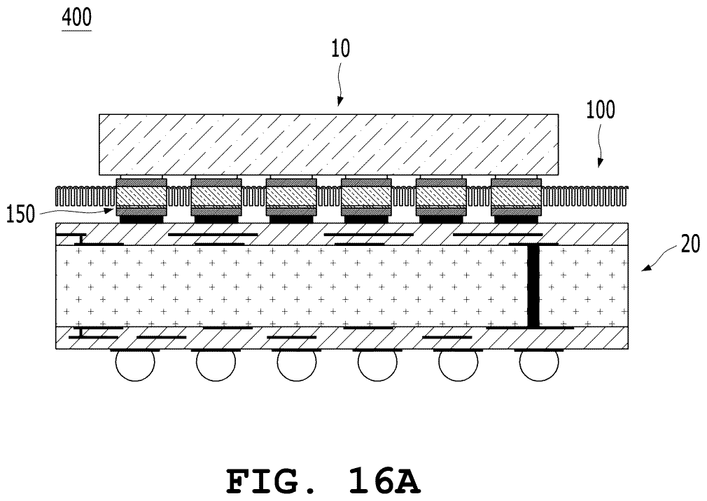

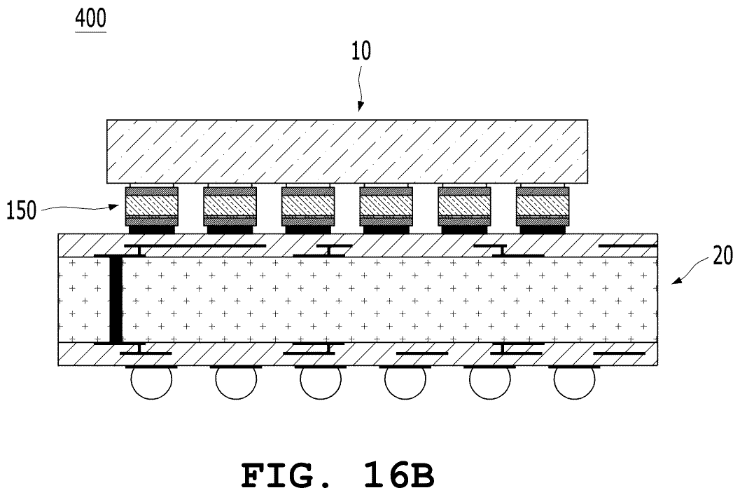

A semiconductor package 400 according to an embodiment of the present disclosure will be described with reference to FIGS. 16A and 16B. FIGS. 16A and 16B are views illustrating the semiconductor package 400 according to the embodiment of the present disclosure.

Referring to FIG. 16A, the semiconductor package 400 according to the embodiment of the present disclosure includes: a semiconductor device 10; a substrate 20 on which the semiconductor device 10 is mounted; and an interposer 100 for electrical connection provided between the semiconductor device 10 and the substrate 20. The interposer 100 for electrical connection includes: a body 110 made of an anodic aluminum oxide film having a plurality of through-holes 111; an electrically conductive material part 130 provided in each of the through-holes 111; and a bonding material part 120 provided in each of the through-holes 111 and provided on at least a part of an upper portion and a lower portion of the electrically conductive material part 130. Here, a seed layer 200 and a first bonding material part 121 are provided on the lower portion of the electrically conductive material part 130, and a second bonding material part 123 is provided on the upper portion of the electrically conductive material part 130.

In FIG. 16A, the interposer 150 for electrical connection illustrated in FIG. 15C is illustrated, but the present disclosure not limited thereto. The is semiconductor package 400 may be formed by employing the configuration of the interposers 150 for electrical connection illustrated in FIGS. 15A, 15B, and 15D.

Referring to FIG. 16B, the semiconductor package 400 may be configured such that, with the body 110 made of the anodic aluminum oxide film removed, the semiconductor device 10 is electrically connected to the substrate 20 through a plurality of micro bumps 150 each of which is formed by sequentially stacking the first bonding material part 121, the electrically conductive material part 130, and the second bonding material part 123.

The semiconductor package 400 includes: the semiconductor device 10; the substrate 20 on which the semiconductor device 10 is mounted; and the plurality of micro bumps 150 provided between the semiconductor device 10 and the substrate 20. The micro bumps 150 are formed in a column shape. A plurality of fine trenches 155 having repeated peaks and valleys in the circumferential direction are provided in an outer circumferential surface of each of the micro bumps 150.

In the semiconductor package 400 according to the embodiment of the present disclosure, a terminal 11 of the semiconductor device 10 and a terminal 21 of the substrate 20 are electrically connected to each other by the electrically conductive material part 130, the electrically conductive material part 130 and the terminal 21 of the substrate 20 are boned by the first bonding material part 121, and the electrically conductive material part 130 and the terminal of the semiconductor device 10 are bonded by the second bonding material part 123. The bonding between the bonding material part 120 and the terminals 11 and 21 may be performed through a thermocompression process or a reflow process.

The semiconductor device 10 may be bonded in a flip-chip form on the interposer 100 for electrical connection. The substrate 20 is provided under the interposer 100 for electrical connection. Here, the substrate 20 may be a package substrate that supports the semiconductor device 10 and has a molding layer 300 on an upper surface thereof.

For example, the substrate 20 may include a substrate base 23, and an upper wiring layer 22 and a lower wiring layer 24 formed on upper and lower surfaces of the substrate base 23, respectively. The substrate base 23 of the substrate 20 may be made of at least one material selected from among phenol resin, epoxy resin, and polyimide. For example, the substrate base 23 may include at least one material selected from among FR4, tetrafunctional epoxy, polyphenylene ether, epoxy/polyphenylene oxide, bismaleimide triazine (BT), Thermount, cyanate ester, polyimide, and liquid crystalline polymer. An external connection terminal 25 may be provided under the lower wiring layer 24.

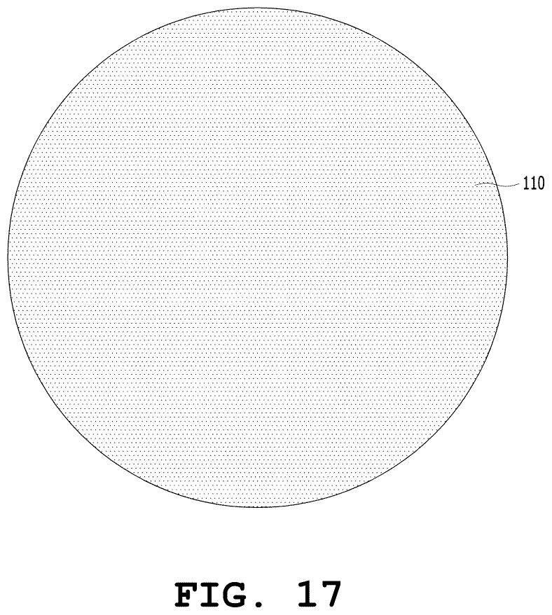

A method of manufacturing the semiconductor package 400 according to the embodiment of the present disclosure will be described with reference to FIGS. 17 to 27.

The method of manufacturing the semiconductor package 400 formed by mounting a semiconductor device 10 on a substrate 20 includes providing an interposer 100 for electrical connection between the semiconductor device 10 and the substrate 20, the interposer including a body 110 made of an anodic aluminum oxide film having a plurality of through-holes 111, an electrically conductive material part 130 provided in each of the through-holes 111, and a bonding material part 120 formed on at least a part of an upper portion and a lower portion of the electrically conductive material part 130.

First, referring to FIG. 17, the body 110 made of the anodic aluminum oxide film is prepared.

The body 110 is manufactured by anodization of a base metal. Pores 112 included in a porous layer 114 may be formed to have a diameter in the range of several nm to several hundreds of nm. The body 100 manufactured through the anodization may have a structure in which a barrier layer 113 formed during the anodization is provided on at least one surface thereof to close one of the top and bottom of the pores 112, or the barrier layer 113 formed during the anodization is removed from the least one surface thereof to expose the top and bottom of the pores 112. When the body 110 is manufactured to have the same size and shape as those of a wafer for manufacturing the semiconductor device 10, wafer level packaging is possible by providing the interposer 100 for electrical connection between the semiconductor device 10 and the substrate 20.

In addition, since it is possible to form the body 110 made of the anodic aluminum oxide film with a thickness of equal to or greater than 100 μm, it is possible to form each micro bump 150 with a uniform height of equal to or greater than 100 μm.

A seed layer 200 is provided under the body 110. The seed layer 200 provided under the body 110 is used in a subsequent plating process of the bonding material part 120 and the electrically conductive material part 130.

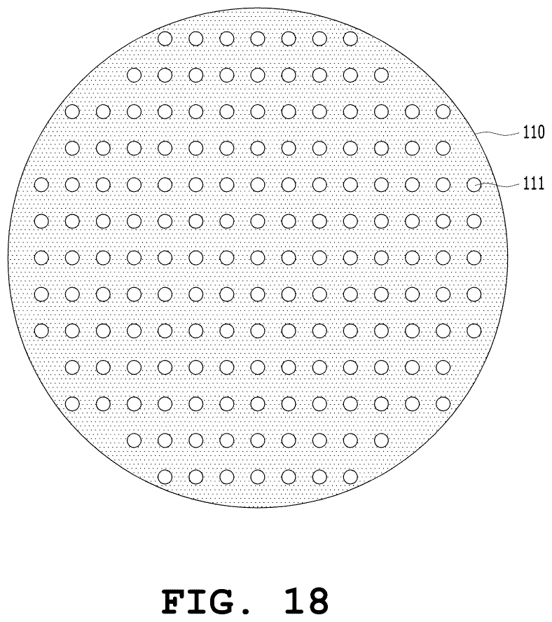

Next, referring to FIG. 18, a through-hole 111 having a width greater than that of the pores 112 is formed in the body 110 separately from the pores 112.

The through-hole 111 may be formed to have a width in the range of several μm to several tens of μm. A plurality of through-holes 111 are formed simultaneously by a single etching process. In addition, since the through-holes 111 are formed by the etching process, the cross-sectional shape of the through-holes 111 is not limited, and the through-holes 111 resulting from the reaction of the anodic aluminum oxide film with an etching solution each have a vertical inner wall. A conductive material fills the inside of each of the through-holes 111 having the vertical inner wall to form a micro bump 150. This is advantageous in terms of efficient electric flow compared to a via conductor that has a non-vertical shape. The through-holes 111 may be formed by forming a photoresist on an upper surface of the body 110, patterning the photoresist to form openings, and then flowing the etching solution through the openings. Thus, the through-holes 111 have a cross-sectional shape that corresponds to the shape of the patterned openings. The cross-sectional shape of the through-holes 111 may be polygonal as well as circular.

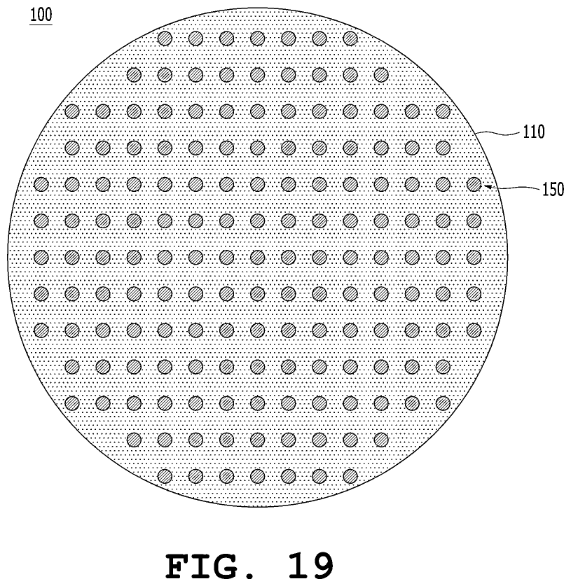

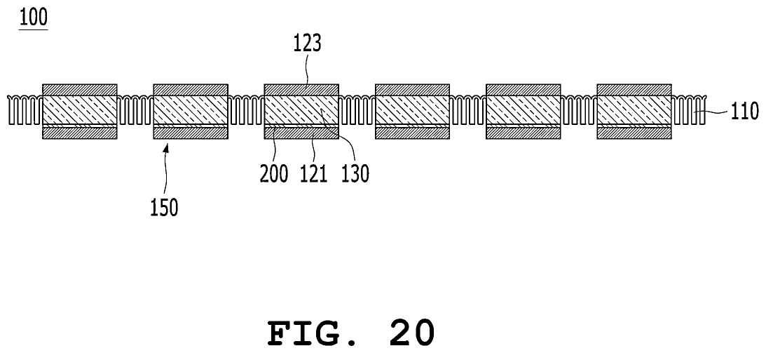

Next, referring to FIGS. 19 and 20, the electrically conductive material part 130 is formed inside each of the through-holes 111, a first bonding material part 121 is formed on a lower portion of the electrically conductive material part 130, and a second bonding material part 123 is formed on an upper portion of the electrically conductive material part 130 to form a micro bump 150. The configuration and manufacturing method of the micro bump 150 and the configuration and manufacturing method of the interposer 100 for electrical connection may include the configurations of the above-described embodiments.

After the second bonding material part 123 is formed, a part of the second bonding material part 123 protruding from the upper surface of the body 110 is removed through a chemical mechanical polishing (CMP) process.

As a result, the bonding material part 120 is provided both on and under the electrically conductive material part 130. The electrically conductive material part 130 may be made of at least one selected from among Cu, Al, W, Au, Ag, Mo, and Ta. The bonding material part 120 may be made of at least one selected from among Sn, AgSn, Au, PbSn, SnAgCu, SnAgBi, AuSn, In, InSn, and an alloy containing Sn. For example, the electrically conductive material part 130 may be made of copper (Cu) or an alloy containing copper (Cu) as a main component, and the bonding material part 120 may be made of tin (Sn) or an alloy containing tin (Sn) as a main component.

Since the micro bump 150 is formed in a cylindrical shape, it has a larger volume than that in the case of a spherical shape, and since the electrically conductive material part 130 is provided in a cylindrical shape, it has an effect of reducing the current density and thermal energy density concentrated on the micro bump 150.

The body 110 having the through-holes 111 serves as a mold for electroplating in manufacturing the micro bump 150. Since the micro bump 150 is manufactured in each of the through-holes 111 by the plating process, the dense characteristics of the electrically conductive material part 130 can be improved. As a result, it is possible to manufacture a highly reliable micro bump 150 due to a reduced current resistance. In addition, since the micro bump 150 is manufactured in each of the through-holes 111 by the plating process, shape precision can be improved and various cross-sectional shapes can be implemented. In addition, even when a plurality of micro bumps 150 are formed in the body 110, a height deviation between the micro bumps 150 can be minimized, and the volumes of the first bonding material part 121 and the second bonding material part 123 can be made uniform, thereby improving bonding reliability.

Since the body 110 made of the anodic aluminum oxide film includes a large number of pores 112, at least portions of the body 110 are etched to form the through-holes 111, and at least one of the first bonding material part 121, the electrically conductive material part 130, and the second bonding material part 123 is formed in each of the through-holes 111, a plurality of fine trenches 155 are provided in a side surface of the micro bump 150 as a result of contact between the micro bump and the pores 112 of the body 110. With the configuration of the fine trenches 155, the surface area of the micro bump 150 can be further increased.

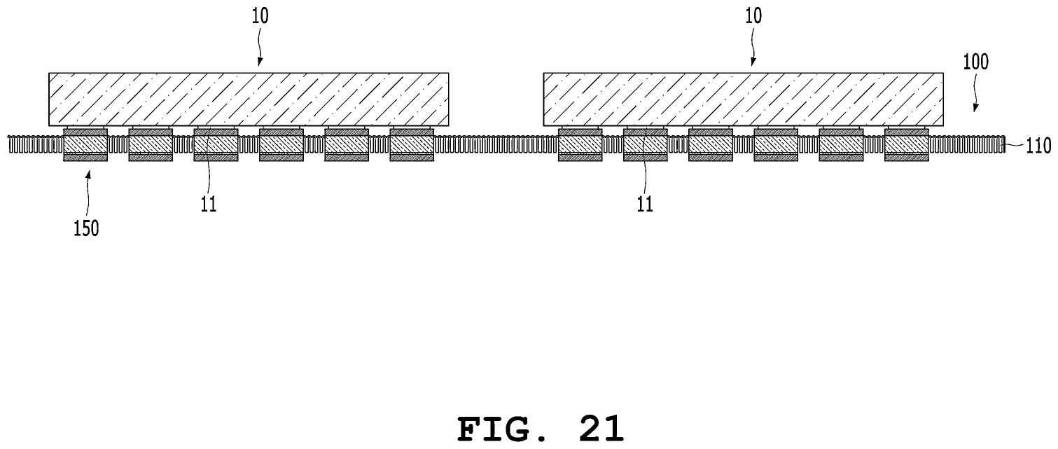

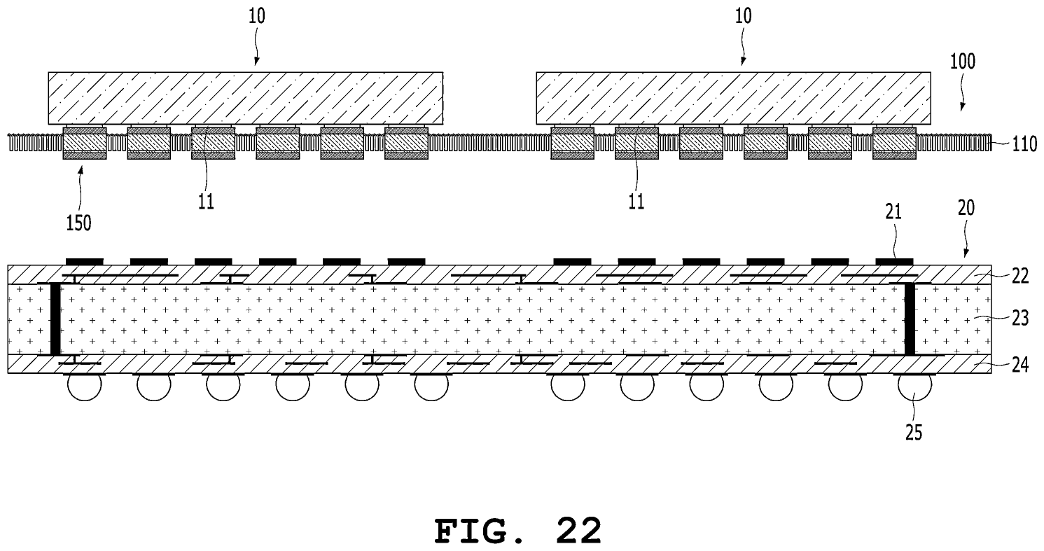

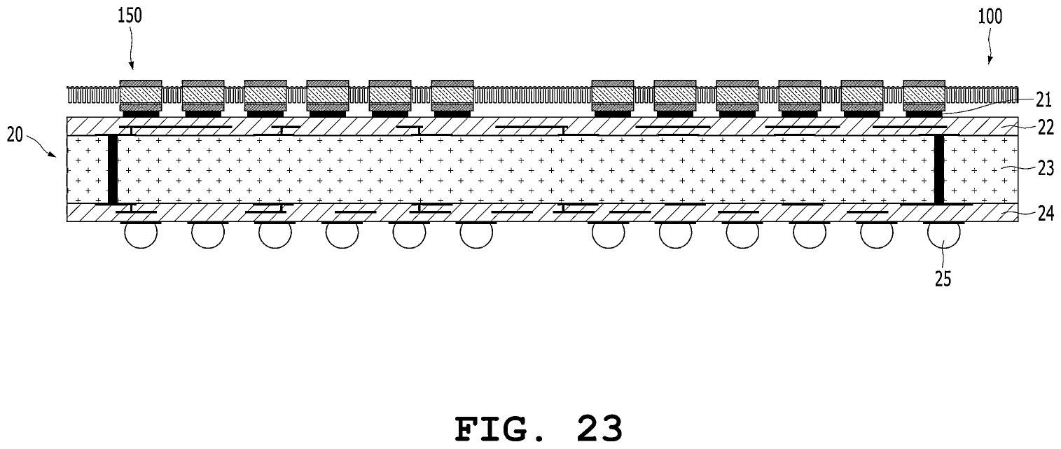

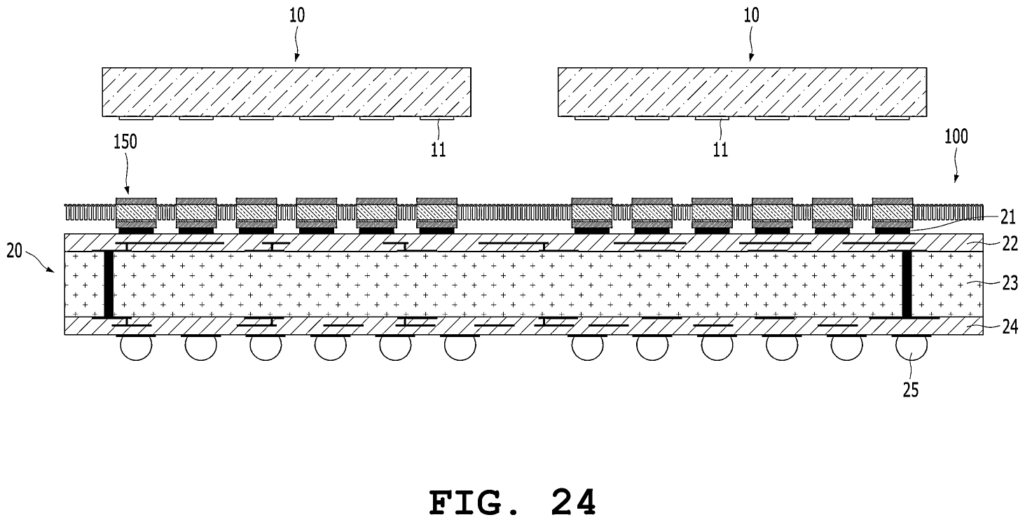

Next, the step of providing the interposer 100 for electrical connection between the semiconductor device 10 and the substrate 20 is performed. This step may be achieved by (i) bonding the semiconductor device 10 to the interposer 100 for electrical connection first and then bonding the interposer 100 for electrical connection to the substrate 20 (FIGS. 21 and 22) or (ii) bonding the interposer 100 for electrical connection to the substrate 20 first and then bonding the semiconductor device 10 to the interposer 100 for electrical connection (FIGS. 23 and 24).

First, referring to FIG. 21, the semiconductor device 10 is mounted on an upper surface of the interposer 100 for electrical connection. Each terminal 11 of the semiconductor device 10 is bonded to correspond to each second bonding material part 123 of the interposer 100 for electrical connection. Although FIG. 21 illustrates that two semiconductor devices 10 are mounted on the upper surface of the interposer 100 for electrical connection, the number of the semiconductor devices 10 is not limited thereto and the semiconductor devices 10 may be mounted in a sufficient number to enable wafer level packaging.

Next, referring to FIG. 22, the interposer 100 for electrical connection on which the semiconductor devices 10 are mounted may be transferred to the substrate 20 and bonded on an upper surface of the substrate 20. On the upper surface of the substrate 20, each terminal 21 of the substrate 20 is manufactured and provided in advance at a position corresponding to each micro bump 150 of the interposer 100 for electrical connection. Each terminal 21 of the substrate 20 is bonded to correspond to each first bonding material part 121 of the interposer 100 for electrical connection.

Meanwhile, as illustrated in FIGS. 23 and 24, the interposer 100 for electrical connection may be provided on the upper surface of the substrate 20 first, and then the semiconductor devices 10 may be transferred and provided on the upper surface of the interposer 100 for electrical connection. Each micro bump 150 is bonded to each terminal 21 of the substrate 20 through the first bonding material part 121 and is bonded to each terminal 11 of the semiconductor devices 10 through the second bonding material part 123. With this, the semiconductor package 400 includes the semiconductor devices 10, the substrate 20 on which the semiconductor devices 10 are mounted, and the interposer 100 for electrical connection provided between the semiconductor devices 10 and the substrate 20.

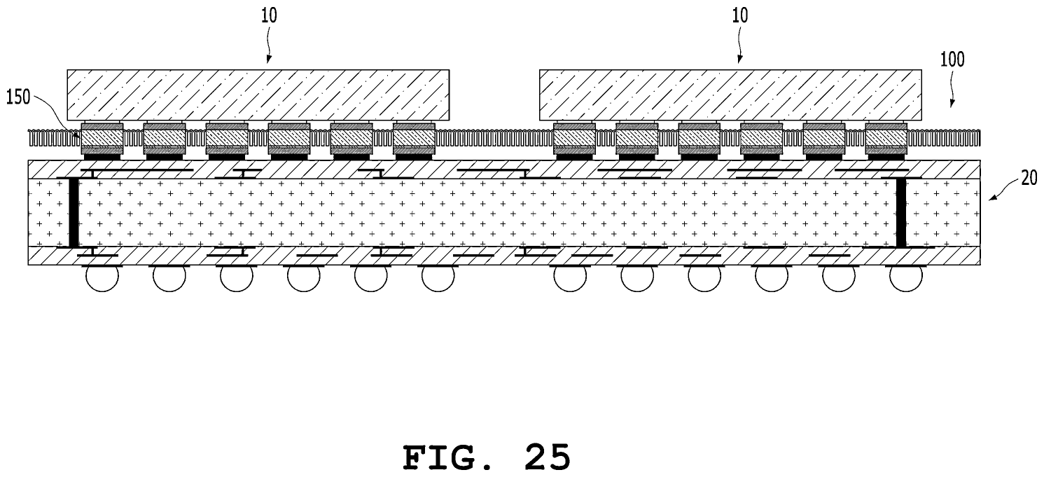

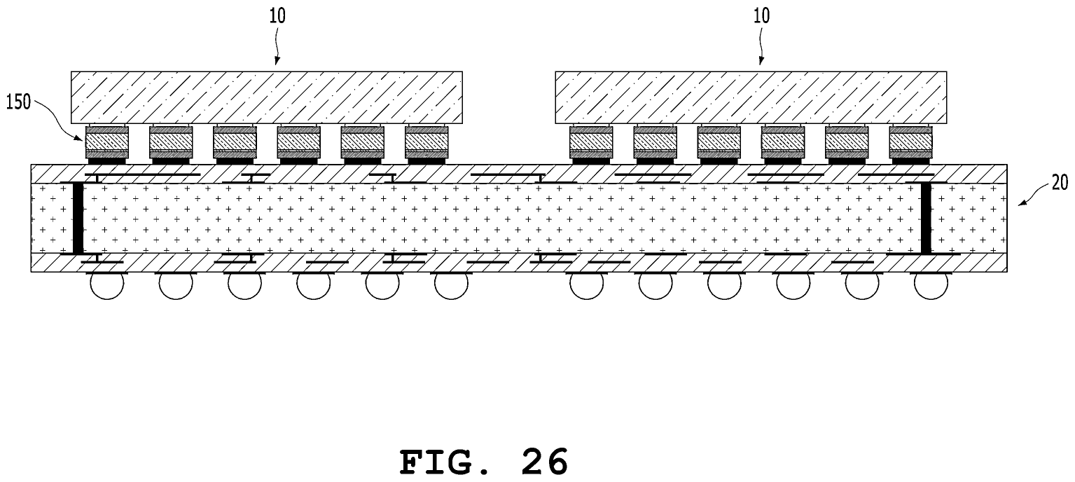

The semiconductor package 400 may be configured such that the body 110 made of the anodic aluminum oxide film is provided as illustrated in FIG. 25, or may be configured such that the body 110 is removed and only the micro bumps 150 remain as illustrated in FIG. 26. The body 110 may be selectively removed by a solution that selectively reacts only with the anodic aluminum oxide film.

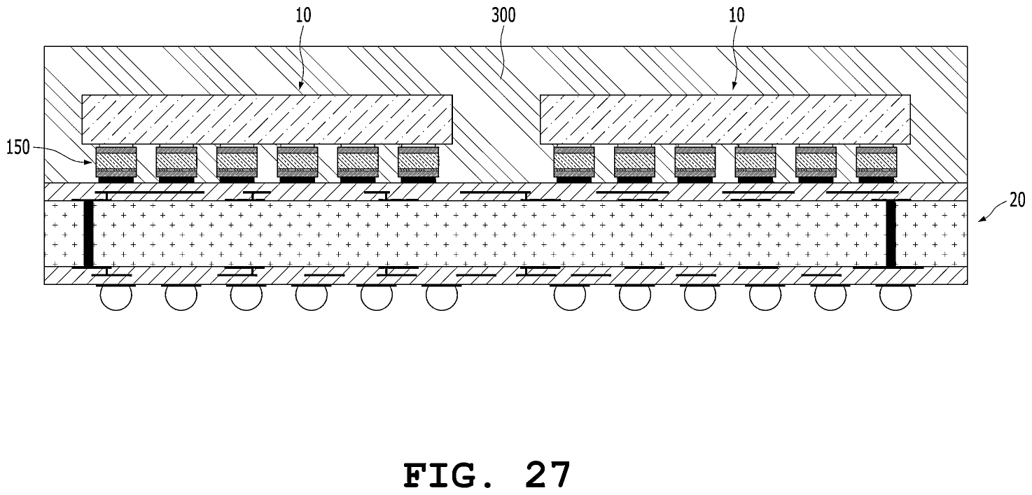

Next, referring to FIG. 27, a molding layer 300 for sealing the semiconductor devices 10 is formed. The molding layer 300 may include a polymer material. In some embodiments, the molding layer 300 may be a molding compound layer. The molding compound layer may include an epoxy-based resin in which a filler is dispersed. The filler may include insulating fibers, insulating particles, other suitable elements, or a combination thereof. Thereafter, a part of the molding layer 300 may be removed by chemical mechanical polishing (CMP) to expose upper surfaces of the semiconductor devices 10. Next, each individualized semiconductor package 400 is completed by cutting along a cutting line.

As described above, the semiconductor package 400 according to the embodiment of the present disclosure electrically connects the semiconductor device 10 and the substrate 20 each other by using the micro bump 150. Meanwhile, conventionally, bumps are manufactured by stacking the materials of the bumps on each terminal 11 of the semiconductor device 10, so the manufacturing process is cumbersome and the production yield is not high. However, according to the embodiment of the present disclosure, since the semiconductor device 10 and the substrate 20 are bonded using the separately manufactured interposer 100 for electrical connection, the manufacturing process is simple and the production yield is improved.

In addition, when the semiconductor device 10 and the substrate 20 are bonded using only solder bumps, there is a high possibility that a solder bump is melted and short-circuited with an adjacent solder bump. However, according to the embodiment of the present disclosure, by adopting the configuration of the electrically conductive material part 130 provided between the upper and lower bonding material parts 120 through the plating process, the possibility of a short-circuit between adjacent micro bumps 150 can be minimized even when the upper and lower bonding material parts 120 are melted.

In addition, when the semiconductor device 10 and the substrate 20 are bonded using only solder bumps, a problem occurs in that the current density and thermal energy are concentrated on a bump connection part. However, according to the embodiment of the present disclosure, by adopting the configuration of the electrically conductive material part 130 provided between the upper and lower bonding material parts 120, it is possible to alleviate the phenomenon in which the current density and thermal energy are concentrated on the micro bump 150.

### Configuration in Which Semiconductor Package 400 is Mounted on Circuit Board 600

Hereinafter, a configuration in which a semiconductor package 400 having a micro bump 150 is mounted on a circuit board 600 and a manufacturing method thereof will be described.

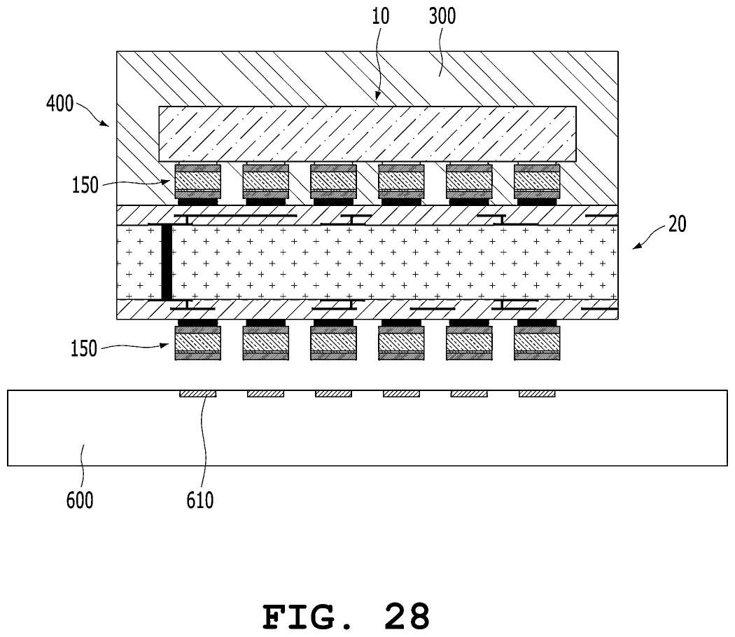

Referring to FIG. 28, an interposer 100 for electrical connection according to an embodiment of the present disclosure may be provided under a substrate 20. That is, the semiconductor package 400 according to the embodiment of the present disclosure may include: a semiconductor device 10; the substrate 20 on which the semiconductor device 10 is mounted; and the interposer 100 for electrical connection provided under the substrate 20. The interposer 100 for electrical connection may be additionally provided between the semiconductor device 10 and the substrate 20.

The interposer 100 for electrical connection may be provided between the substrate 20 and the circuit board 600 to bond the semiconductor package 400 to the circuit board 600. In this case, each micro bump 150 of the interposer 100 for electrical connection may be provided at a position corresponding to each terminal 610 of the circuit board 600. A first bonding material part 121 of each micro bump 150 is bonded to each terminal 610 of the circuit board 600, and a second bonding material part 123 of each micro bump 150 is bonded to each terminal 21 of the substrate 20.

A method of manufacturing the semiconductor package 400 includes: providing an interposer 100 for electrical connection under a substrate 20, the interposer including a body 110 made of an anodic aluminum oxide film having a plurality of through-holes 111, an electrically conductive material part 130 provided in each of the through-holes 111, and first and second bonding material parts 121 and 123 formed on upper and lower portions of the electrically conductive material part 130; and bonding the second bonding material part 123 to a terminal 21 of the substrate 20.

Although FIG. 28 illustrates a state in which the body 110 made of the anodic aluminum oxide film is removed, a configuration in which the body 110 made of the anodic aluminum oxide film is provided in FIG. 28 is also included in one embodiment of the present disclosure.

That is, the semiconductor package 400 includes the semiconductor device 10, the substrate 20 on which the semiconductor device 10 is mounted, and a plurality of micro bumps 150 provided under the substrate 20. The micro bumps 150 are formed in a column shape. A plurality of fine trenches 155 having repeated peaks and valleys in the circumferential direction are provided in an outer circumferential surface of each of the micro bumps 150.

As described above, the semiconductor package 400 according to the embodiment of the present disclosure is electrically connected to the circuit board 600 by using the micro bump 150. In addition, conventionally, bumps are manufactured by stacking the materials of the bumps on each terminal 21 of the semiconductor package 400, so the manufacturing process is cumbersome and the production yield is not high. However, according to the embodiment of the present disclosure, since the semiconductor package 400 and the circuit board 600 are bonded using the separately manufactured interposer 100 for electrical connection, the manufacturing process is simple and the production yield is improved.

In addition, when the semiconductor package 400 and the circuit board 600 are bonded using only solder bumps, there is a high possibility that a solder bump is melted and short-circuited with an adjacent solder bump. However, according to the embodiment of the present disclosure, by adopting the configuration of the electrically conductive material part 130 provided between the upper and lower bonding material parts 120 through the plating process, the possibility of a short-circuit between adjacent micro bumps 150 can be minimized even when the upper and lower bonding material parts 120 are melted.

In addition, when the semiconductor package 400 and the circuit board 600 are bonded using only solder bumps, a problem occurs in that the current density and thermal energy are concentrated on a bump connection part. However, according to the embodiment of the present disclosure, by adopting the configuration of the electrically conductive material part 130 provided between the upper and lower bonding material parts 120, it is possible to alleviate the phenomenon in which the current density and thermal energy are concentrated on the micro bump 150.

### Multi-Layer Stacked Semiconductor Device 500

Hereinafter, a multi-layer stacked semiconductor device 500 having a micro bump 150 and a manufacturing method thereof will be described.

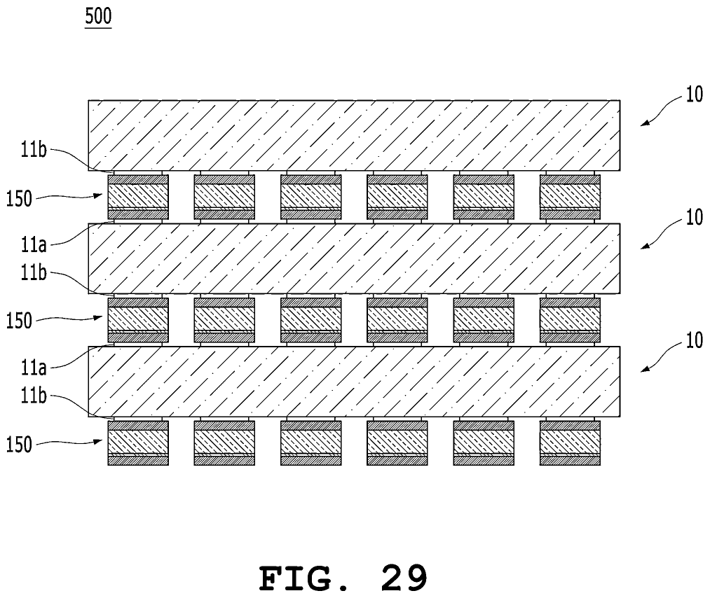

Referring to FIG. 29, the multi-layer stacked semiconductor device 500 may be configured such that an interposer 100 for electrical connection according to an embodiment of the present disclosure is provided between semiconductor devices 10 adjacent in the upper and lower directions to electrically connect the semiconductor devices 10 adjacent in the upper and lower directions to each other. That is, the multi-layer stacked semiconductor device 500 includes a plurality of semiconductor devices 10 and the interposer 100 for electrical connection provided between the semiconductor devices 10.

Each first bonding material part 121 of the interposer 100 for electrical connection is bonded to each upper terminal 11a of a semiconductor device 10 located therebelow, and each second bonding material part 123 is bonded to each lower terminal 11b of a semiconductor device 10 located thereabove. With this, the multi-layer stacked semiconductor device 500 in which the semiconductor devices 10 are stacked in multiple stages is formed.

A method of manufacturing the multi-layer stacked semiconductor device 500 includes: providing an interposer 100 for electrical connection between a plurality of semiconductor devices 10, the interposer including a body 110 made of an anodic aluminum oxide film having a plurality of through-holes 111, an electrically conductive material part 130 provided in each of the through-holes 111, and first and second bonding material part 121 and 123 formed on upper and lower portions of the electrically conductive material part 130; and bonding the first bonding material part 121 to a terminal 11a of a semiconductor device 10 located thereabove and bonding the second bonding material part 123 to a terminal 11b of a semiconductor device 10 located therebelow. The method may further include removing the body 110 made of the anodic aluminum oxide film after the semiconductor devices 10 adjacent in the upper and lower directions are all bonded together through a plurality of micro bumps 150.

Although FIG. 29 illustrates a state in which the body 110 made of the anodic aluminum oxide film is removed, a configuration in which the body 110 made of the anodic aluminum oxide film is provided in FIG. 29 is also included in one embodiment of the present disclosure.

The multi-layer stacked semiconductor device 500 includes the plurality of semiconductor devices 10 and the plurality of micro bumps 150 provided between the semiconductor devices 10. The micro bumps 150 are formed in a column shape. A plurality of fine trenches 155 having repeated peaks and valleys in the circumferential direction are provided in an outer circumferential surface of each of the micro bumps 150. The fine trenches 155 have a corrugated shape in which peaks and valleys with a depth in the range of 20 nm to 1 μm are repeated in the circumferential direction and thus have an effect of increasing the surface area of a side surface of the micro bump 150.

As described above, the multi-layer stacked semiconductor device 500 according to the embodiment of the present disclosure electrically connects the semiconductor devices 10 adjacent in the upper and lower directions to each other by using the micro bump 150. In addition, according to the embodiment of the present disclosure, since the semiconductor devices 10 adjacent in the upper and lower directions are bonded using the separately manufactured interposer 100 for electrical connection, the manufacturing process is simple and the production yield is improved.

In addition, when the semiconductor devices 10 adjacent in the upper and lower directions are bonded using only solder bumps, there is a high possibility that a solder bump is melted and short-circuited with an adjacent solder bump. However, according to the embodiment of the present disclosure, by adopting the configuration of the electrically conductive material part 130 provided between the upper and lower bonding material parts 120 through the plating process, the possibility of a short-circuit between adjacent micro bumps 150 can be minimized even when the upper and lower bonding material parts 120 are melted.

In addition, when the semiconductor devices 10 adjacent in the upper and lower directions are bonded using only solder bumps, a problem occurs in that the current density and thermal energy are concentrated on a bump connection part. However, according to the embodiment of the present disclosure, by adopting the configuration of the electrically conductive material part 130 provided between the upper and lower bonding material parts 120, it is possible to alleviate the phenomenon in which the current density and thermal energy are concentrated on the micro bump 150.

### Display

Hereinafter, a display having a micro bump 150 and a manufacturing method thereof will be described.

A display according to an embodiment of the present disclosure includes: a semiconductor device 10; a substrate 20 on which the semiconductor device 10 is mounted; and an interposer 100 for electrical connection provided between the semiconductor device 10 and the substrate 20. The interposer 100 for electrical connection includes: a body 110 made of an anodic aluminum oxide film having a plurality of through-holes 111; an electrically conductive material part 130 provided in each of the through-holes 111; and a bonding material part 120 provided in each of the through-holes 111 and provided on at least a part of an upper portion and a lower portion of the electrically conductive material part 130.

Here, the semiconductor device 10 is a semiconductor LED, and includes a mini LED and a micro LED. In addition, the substrate 20 may be a circuit board having wiring lines.

The display according to the embodiment of the present disclosure may be configured such that the body 110 made of the anodic aluminum oxide film is removed selectively.

Each terminal 11 of the semiconductor device 10 and each terminal 21 of the substrate 20 are electrically connected to each other by an electrically conductive material part 130, the electrically conductive material part 130 and each terminal of the substrate 20 are boned by a first bonding material part 121, and the electrically conductive material part 130 and each terminal 11 of the semiconductor device 10 are bonded by a second bonding material part 123.

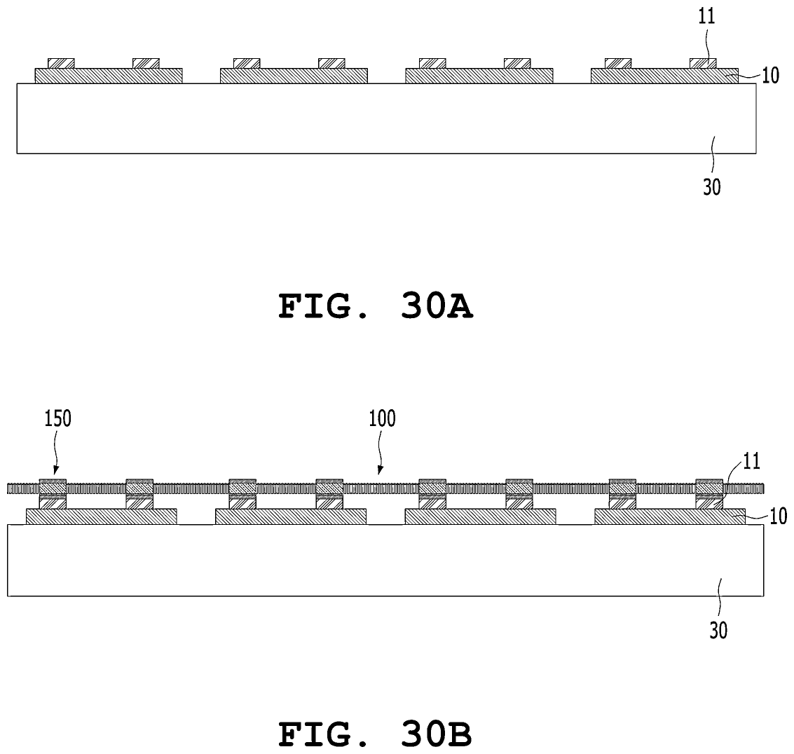

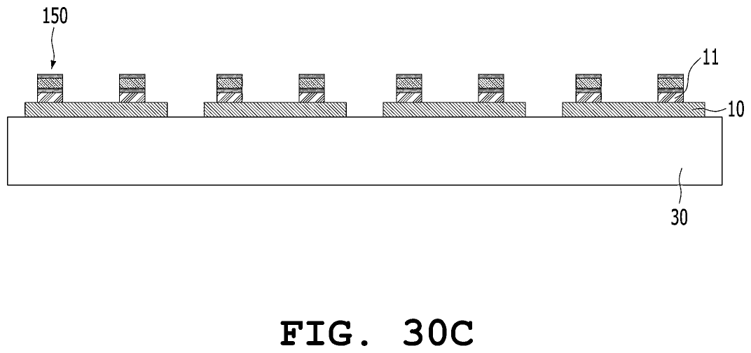

Hereinafter, a method of manufacturing the display according to the embodiment of the present disclosure will be described with reference to FIGS. 30A to 33B.

The method of manufacturing the display according to the embodiment of the present disclosure includes: providing an interposer 100 for electrical connection between a semiconductor device 10 and a substrate 20, the interposer including a body 110 made of an anodic aluminum oxide film having a plurality of through-holes 111, an electrically conductive material part 130 provided in each of the through-holes 111, and first and second bonding material parts 121 and 123 formed on upper and lower portions of the electrically conductive material part 130; and bonding the first bonding material part 121 to a terminal 21 of the substrate 20 and bonding the second bonding material part 123 to a terminal 11 of the semiconductor device 10.

First, referring to FIG. 30A, a plurality of semiconductor devices 10 are fabricated and disposed on a growth substrate 30. The growth substrate 30 may be configured as a conductive substrate or an insulating substrate. For example, the growth substrate 30 may be made of at least one selected from among sapphire, SiC, Si, GaAs, GaN, ZnO, Si, GaP, InP, Ge, and Ga₂0₃.

Each of the semiconductor devices 10 may include a first semiconductor layer, a second semiconductor layer, and an active layer provided between the first semiconductor layer and the second semiconductor layer. The first semiconductor layer, the active layer, and the second semiconductor layer may be formed using metal organic chemical vapor deposition (MOCVD), chemical vapor deposition (CVD), plasma-enhanced chemical vapor deposition (PECVD), molecular-beam epitaxy (MBE), hydride vapor phase epitaxy (HVPE), or the like. The first semiconductor layer may be implemented, for example, as a p-type semiconductor layer. A p-type semiconductor layer may be made of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, AlInN, and the like, and the layer may be doped with a p-type dopant such as Mg, Zn, Ca, Sr, or Ba. The second semiconductor layer may include, for example, an n-type semiconductor layer. An n-type semiconductor layer may be made of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, AlInN, and the like, and the layer may be doped with an n-type dopant such as Si, Ge, or Sn. The active layer is a region where electrons and holes are recombined. As the electrons and the holes are recombined, the active layer transits to a low energy level and generates light having a wavelength corresponding thereto. The active layer may be made of a semiconductor material having a composition formula of InxAlyGa1-x-yN (0≤x≤1, 0≤y≤1, 0≤x+y≤1) and may have a single quantum well structure or a multi-quantum well (MQW) structure. In addition, the active layer may have a quantum wire structure or a quantum dot structure.

Each of the semiconductor devices 10 includes at least two terminals 11. The terminals 11 may be all provided on one surface of the semiconductor device 10 or may be respectively provided on opposite surfaces of the semiconductor device 10. However, in FIGS. 30A, 30B, and 30C, it is illustrated that the terminals 11 are all provided on one surface of the semiconductor device 10. Each of the terminals 11 may include at least one layer and may be made of various conductive materials including a metal, conductive oxide, and conductive polymer.

The semiconductor devices 10 are separated into individual pieces by cutting along a cutting line using a laser or the like or by etching.

Meanwhile, in the previous description, the semiconductor devices 10 have been described as being fabricated on the growth substrate 30 and provided on the growth substrate 30. However, the semiconductor devices 10 fabricated on the growth substrate 30 may be provided by being transferred from the growth substrate 30 to a temporary substrate or an intermediate substrate. Thus, the embodiment of the present disclosure includes a case in which the growth substrate 30 illustrated in FIG. 30A is a temporary substrate or an intermediate substrate.

Next, referring to FIG. 30B, a plurality of micro bumps 150 are provided on the semiconductor devices 10. Each micro bump 150 of the plurality of micro bumps 150 is positioned to correspond to each terminal 11 of the semiconductor devices 10. Specifically, two terminals 11 are provided on one surface of one semiconductor device 10, and two micro bumps 150 of the plurality of micro bumps 150 are provided to correspond to the two terminals 11.

Next, referring to FIG. 30C, the first bonding material part 121 of each micro bump 150 is bonded to each terminal 11 of the semiconductor devices 10. Next, only the body 110 made of the anodic aluminum oxide film is selectively removed from the micro bumps 150 by using an etching solution.

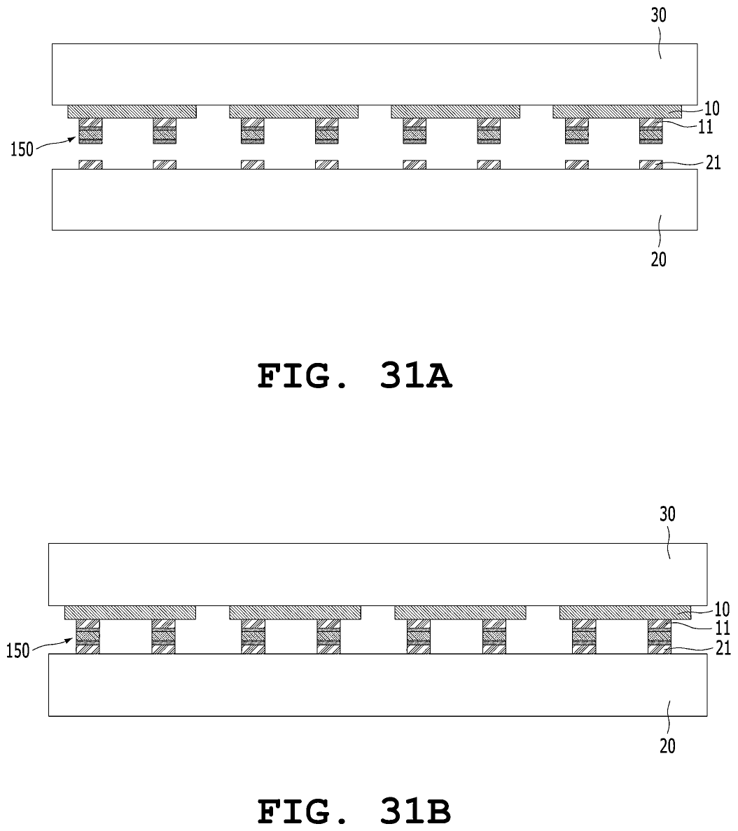

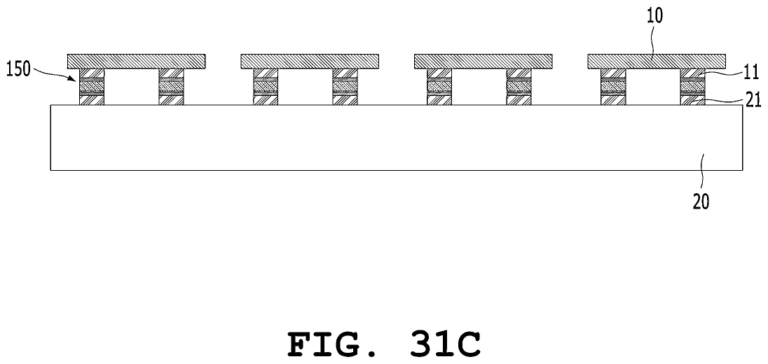

Next, referring to FIG. 31A, the semiconductor devices 10 are inverted and transferred toward the substrate 20. Terminals 21 are provided on an upper surface of the substrate 20 at positions corresponding to the terminals 11 of the semiconductor devices 10. After aligning the positions of the terminals 11 of the semiconductor devices 10 and the positions of the terminals 21 of the substrate 20 with each other, the semiconductor devices 10 and the substrate 20 are moved relative to each other to approach each other.

Here, the substrate 20 is a display substrate and may include various materials. For example, the substrate 20 may be made of a transparent glass material having SiO2 as a main component. However, the substrate 20 is not limited thereto, and may be made of a transparent plastic material and thus have solubility. The plastic material may be an organic substance selected from among organic insulating substances, including polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP). In the case of a bottom emission type in which an image is implemented in a direction of the substrate 20, the substrate 20 is required to be made of a transparent material. However, in the case of a top emission type in which an image is implemented in a direction opposite to the substrate 20, the substrate 20 is not necessarily required to be made of a transparent material. In this case, the substrate 20 may be made of a metal. In the case of forming the substrate 20 using a metal, the substrate 20 may be made of at least one metal selected from among iron, chromium, manganese, nickel, titanium, molybdenum, stainless steel (SUS), Invar alloy, Inconel alloy, and Kovar alloy, but is not limited thereto.

Next, referring to FIG. 31B, the semiconductor devices are bonded to the substrate 20. The second bonding material part 123 of each micro bump 150 and each terminal 21 of the substrate 20 are bonded together.

Next, referring to FIG. 31C, the growth substrate 30 10 is separated from the semiconductor devices 10. For example, the growth substrate 30 may be separated from the semiconductor devices 10 by a laser lift-off process.

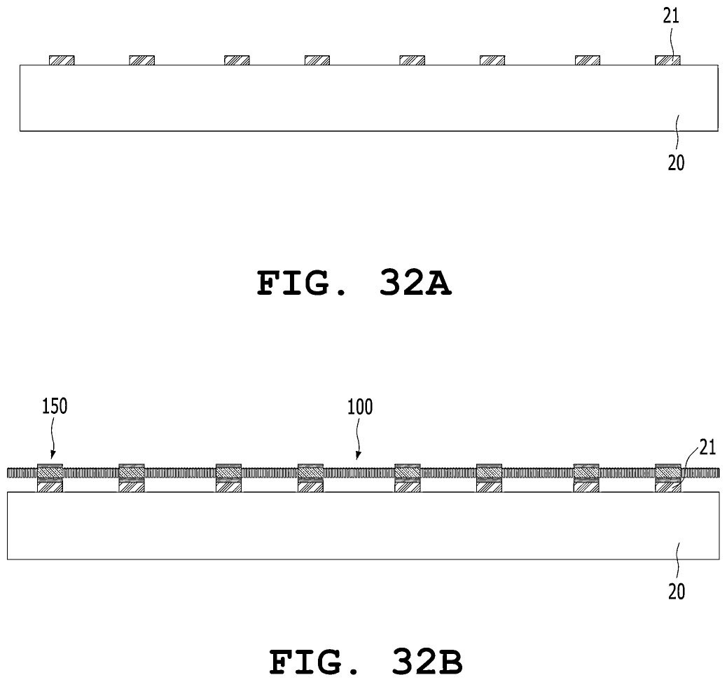

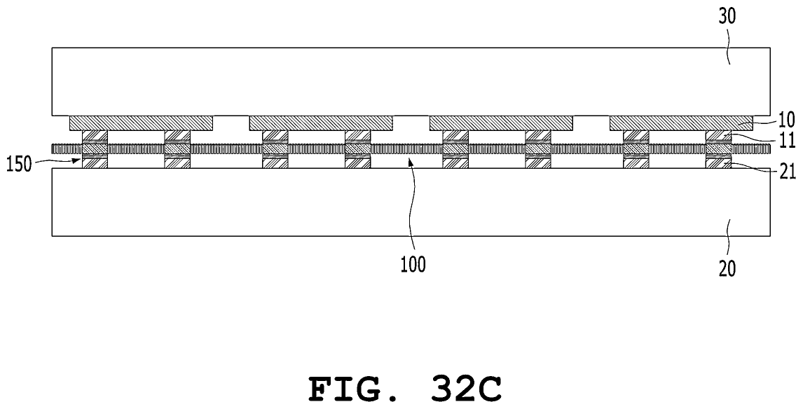

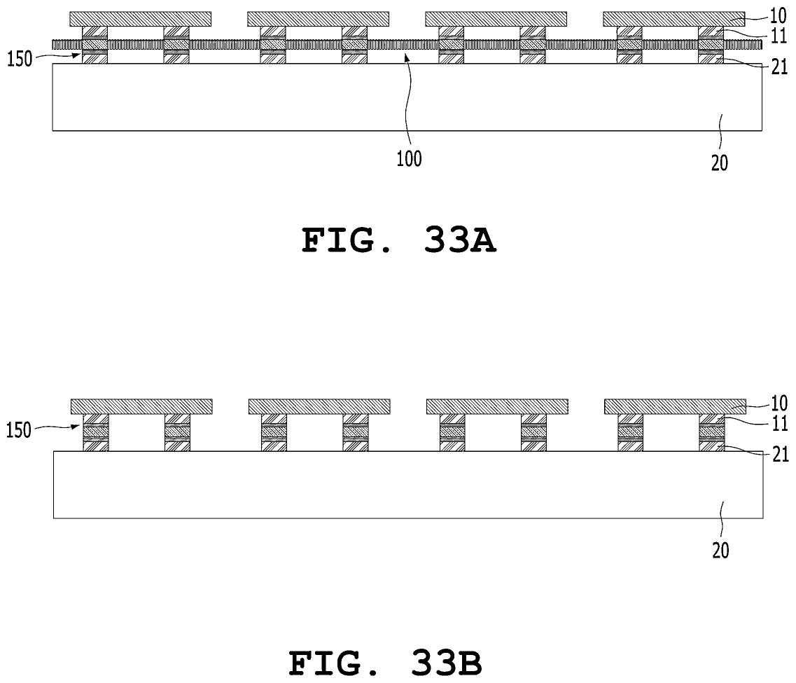

In FIGS. 30A to 31C, it has been described that the semiconductor devices 10 are bonded to the interposer 100 for electrical connection first and then bonded to the substrate 20. However, as illustrated in FIGS. 32A to 33B, the display may be manufactured with a different process order, i.e., bonding the interposer 100 for electrical connection to the substrate 20 first and then bonding the semiconductor devices 10 to the interposer.

First, referring to FIG. 32A, the substrate 20 having the terminals 21 on the upper surface thereof is prepared.

Next, referring to FIG. 32B, the interposer 100 is aligned on the substrate 20 is aligned on the substrate 20, and the first bonding material part 121 of each micro bump 150 is bonded to each terminal 21 of the substrate 20.

Next, referring to FIG. 32C, the semiconductor devices 10 fabricated on the growth substrate 30 are positioned on the interposer 100 for electrical connection, and then each terminal 11 of the semiconductor devices 10 is bonded to the second bonding material part 123 of each micro bump 150. Here, the semiconductor devices 10 may be in a state of being supported by the growth substrate 30, or may be in a state of being supported by a temporary substrate or an intermediate substrate after being fabricated on the growth substrate 30 and transferred to the temporary substrate or the intermediate substrate.

On the other hand, without bonding the first bonding material part 121 to the terminal of the substrate 20 in the structure illustrated in FIG. 32B, the first bonding material part 121 and the second bonding material part 123 may be simultaneously bonded to the respective terminals 11 and 21 by a single bonding process in the structure illustrated in FIG. 32C.

Next, referring to FIG. 33A, the growth substrate 30 is separated from the semiconductor devices 10. For example, the growth substrate 30 may be separated from the semiconductor devices 10 by a laser lift-off process.

Next, as illustrated in FIG. 33B, only the body 110 made of the anodic aluminum oxide film is selectively removed from the interposer 100 for electrical connection by using an etching solution. With this, the semiconductor devices 10 are electrically connected to the substrate 20 by the plurality of micro bumps 150. Specifically, each micro bump 150 is bonded to each terminal 21 of the substrate 20 through the first bonding material part 121, and each micro bump 150 is bonded to each terminal 11 of the semiconductor devices 10 through the second bonding material part 123.

The display including the semiconductor device 10 such as a mini LED or a micro LED includes the semiconductor device 10 such as a mini LED or a micro LED, the substrate 20 on which the semiconductor device 10 is mounted, and a plurality of micro bumps 150 provided between the semiconductor device 10 and the substrate 20. The micro bumps 150 are formed in a column shape. A plurality of fine trenches 155 having repeated peaks and valleys in the circumferential direction are provided in an outer circumferential surface of each of the micro bumps 150. The fine trenches 155 have a corrugated shape in which peaks and valleys with a depth in the range of 20 nm to 1 μm are repeated in the circumferential direction and thus have an effect of increasing the surface area of a side surface of the micro bump 150.

The semiconductor device 10, such as a mini LED or a micro LED, has a small size (horizontal and vertical lengths) in the range of several to tens of micrometers, and thus the distance between the terminals 11 provided on the semiconductor device 10 is also very narrow, ranging from several to tens of micrometers. According to the embodiment of the present disclosure, it is possible to reliably bond the semiconductor device 10 to the terminals 21 of the substrate 20 even within the above dimensional range of the semiconductor device 10.

As described above, the display according to the embodiment of the present disclosure electrically connects the semiconductor device 10 and the substrate 20 to each other by using the micro bump 150. In addition, since the semiconductor device 10 and the substrate 20 are bonded using the separately manufactured interposer 100 for electrical connection, the manufacturing process is simple and the production yield is improved.

When the semiconductor device 10 and the substrate 20 are bonded using only solder bumps, there is a high possibility that a solder bump is melted and short-circuited with an adjacent solder bump. However, according to the embodiment of the present disclosure, by adopting the configuration of the electrically conductive material part 130 provided between the upper and lower bonding material parts 120 through the plating process, the possibility of a short-circuit between adjacent micro bumps 150 can be minimized even when the upper and lower bonding material parts 120 are melted.

In addition, when the semiconductor device 10 and the substrate 20 are bonded using only solder bumps, a problem occurs in that the current density and thermal energy are concentrated on a bump connection part. However, according to the embodiment of the present disclosure, by adopting the configuration of the electrically conductive material part 130 provided between the upper and lower bonding material parts 120, it is possible to alleviate the phenomenon in which the current density and thermal energy are concentrated on the micro bump 150.

Although the exemplary embodiments of the present disclosure have been described for illustrative purposes, those skilled in the art will appreciate that various modifications, additions, and substitutions are possible, without departing from the scope and spirit of the present disclosure as disclosed in the accompanying claims.

### DESCRIPTION OF THE REFERENCE NUMERALS IN THE DRAWINGS

10: semiconductor device
20: substrate
100: interposer for electrical connection
110: body
120: bonding material part
130: electrically conductive material part
200: seed layer
300: molding layer
400: semiconductor package
500: multi-layer stacked semiconductor device
600: circuit board

1. (canceled)

2. (canceled)

3. (canceled)

4. (canceled)

5. (canceled)

6. (canceled)

7. (canceled)

8. A micro bump, comprising:
an electrically conductive material part;
a bonding material part provided on at least a part of an upper portion and a lower portion of the electrically conductive material part; and
a plurality of fine trenches provided in a side surface of the electrically conductive material part.

9. The micro bump of claim 8, wherein the fine trenches are provided along the entire circumference of the side surface of the electrically conductive material part.

10. The micro bump of claim 8, wherein the bonding material part includes:
a first bonding material part provided on the lower portion of the electrically conductive material part; and
a second bonding material part provided on the upper portion of the electrically conductive material part.

11. The micro bump of claim 10, further comprising:
a seed layer provided between the first bonding material part and the electrically conductive material part.

12. The micro bump of claim 8, further comprising:
a functional layer provided between the electrically conductive material part and the bonding material part.

13. The micro bump of claim 8, wherein the fine trenches are also provided on at least a part of a side surface of the bonding material part.

14. (canceled)

15. (canceled)

16. (canceled)

17. (canceled)
